(19) United States
(12) Patent Application Publication
(10) Pub. No.: US 2025/0081622 A1
(43) Pub. Date: Mar. 6, 2025

(54) BACK-END ACTIVE DEVICE

(71) Applicant: Taiwan Semiconductor Manufacturing Company, Ltd., Hsin-Chu (TW)

(72) Inventors: Hung-Li Chiang, Taipei City (TW); Tsung-En Lee, Taipei City (TW); Jer-Fu Wang, Taipei City (TW); Chao-Ching Cheng, Hsinchu City (TW); Iuliana Radu, Hsinchu County (TW); Cheng-Chi Chuang, New Taipei City (TW); Chih-Sheng Chang, Hsinchu (TW); Ching-Wei Tsai, Hsinchu City (TW)

(21) Appl. No.: 18/531,089

(22) Filed: Dec. 6, 2023

Related U.S. Application Data
(60) Provisional application No. 63/580,893, filed on Sep. 6, 2023.

(51) Int. Cl. H01L 27/06; H01L 21/8258

(52) U.S. Cl. CPC H10D 88/00; H10D 84/08; H10B 12/31; H10B 51/30; H10B 61/22; H10B 63/30

(57) ABSTRACT

Semiconductor structures and formation processes thereof are provided. A semiconductor structure of the present disclosure includes a semiconductor substrate, a plurality of transistors disposed on the semiconductor substrate and comprising a plurality of gate structures extending lengthwise along a first direction, a metallization layer disposed over the plurality of transistors, the metallization layer comprising a plurality of metal layers and a plurality of contact vias, a dielectric layer over the metallization layer, a plurality of dielectric fins extending parallel along the first direction and disposed over the dielectric layer, a semiconductor layer disposed conformally over the plurality of dielectric fins, a source contact and a drain contact disposed directly on the semiconductor layer, and a gate structure disposed over the semiconductor layer and between the source contact and the drain contact.

### PRIORITY DATA

This application claims priority to U.S. Provisional Patent Application No. 63/580,893, filed on Sep. 6, 2023, which is hereby incorporated herein by reference in its entirety.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

IC manufacturing process flow may be generally divided into front-end-of-line (FEOL) processes and back-end-of-line (BEOL) processes. FEOL processes encompass those relating to fabricating active IC devices, such as transistors. BEOL processes refer to those relating to fabricating an interconnect structure that interconnects IC features fabricated at the FEOL level. Larger active devices may be fabricated at the BEOL levels. The industry is actively seeking improvement of these BEOL active devices to serve various purposes.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 illustrates a flow chart of a method for forming a back-end semiconductor device, according to one or more aspects of the present disclosure.

FIGS. 2-12 illustrate fragmentary cross-sectional views of a workpiece at various stages of fabrication of the method in FIG. 1, according to one or more aspects of the present disclosure.

FIGS. 13-16 illustrate fragmentary cross-sectional views of an alternative back-end semiconductor device that may be formed using the method in FIG. 1.

FIG. 17 illustrates a flow chart of another method for forming a back-end semiconductor device, according to one or more aspects of the present disclosure.

FIGS. 18-29 illustrate fragmentary cross-sectional views of an alternative back-end semiconductor device that may be formed using the method in FIG. 17.

FIGS. 30-35 illustrate fragmentary cross-sectional views of alternative back-end semiconductor devices that may be formed using the method in FIG. 17.

FIGS. 36-43 illustrate fragmentary cross-sectional views of semiconductor structures where back-end semiconductor devices of the present disclosure are used for accessing a memory device.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.25 nm to 5.75 nm where manufacturing tolerances associated with depositing the material layer are known to be +/−15% by one of ordinary skill in the art. When describing aspects of a transistor, source/drain region(s) may refer to a source or a drain, individually or collectively, dependent upon the context.

IC manufacturing process flow may be typically divided into front-end-of-line (FEOL) processes and back-end-of-line (BEOL) processes. FEOL processes encompass processes relating to fabricating active IC devices, such as transistors. For example, FEOL processes may include forming isolation features, gate structures, and source/drain features. BEOL processes refer to processes relating to fabricating an interconnect structure that interconnects IC features fabricated at the FEOL level. Due to the special nature of contacts to features of the IC devices, such as contacts to the gate structures and/or the source/drain features, fabrication processes for them sometimes may be referred to as middle-end-of-line (MEOL) processes. To reduce routing or to reduce the number of transistors at the FEOL level, active devices are sometimes fabricated at the BEOL level as well. However, to avoid thermal damages to the FEOL structures, fabrication of back-end active devices is subject to face process temperature restraints. These process temperature restraints may lead to insufficient drive current. Improvements on back-end active devices are needed.

The present disclosure provides back-end active devices and methods of forming the same. The back-end active devices of the present disclosure include a channel region that tracks a three-dimensional (3D) topography to provide greater drive current. Depending on the 3D topography, the back-end active devices of the present disclosure have two configurations—a high drive current configuration and a low leakage configuration. The back-end active devices of the present disclosure may serve as header/footer devices for power gating or access devices for various BEOL memory devices. Power gating is a technique to reduce power consumption of an integrated circuit (IC) device by turning off a part of the IC device when it is not being used or in a power saving mode. Header devices or footer devices may be used to activate power gating. Header devices gate the power (VDD) rails and footer devices gate the ground (VSS) rails. It is desirable to fabricate header/footer devices that provide sufficient drive current without taking up too much space at the FEOL level.

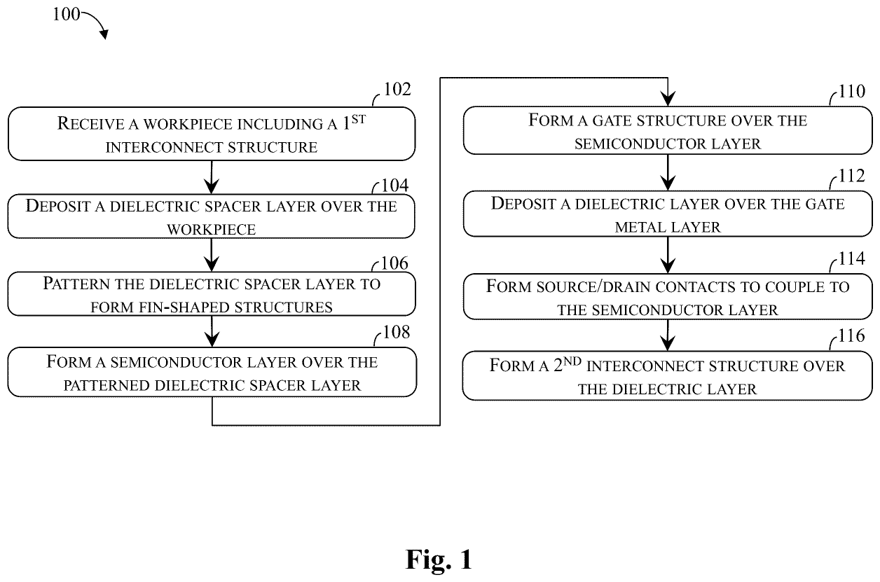

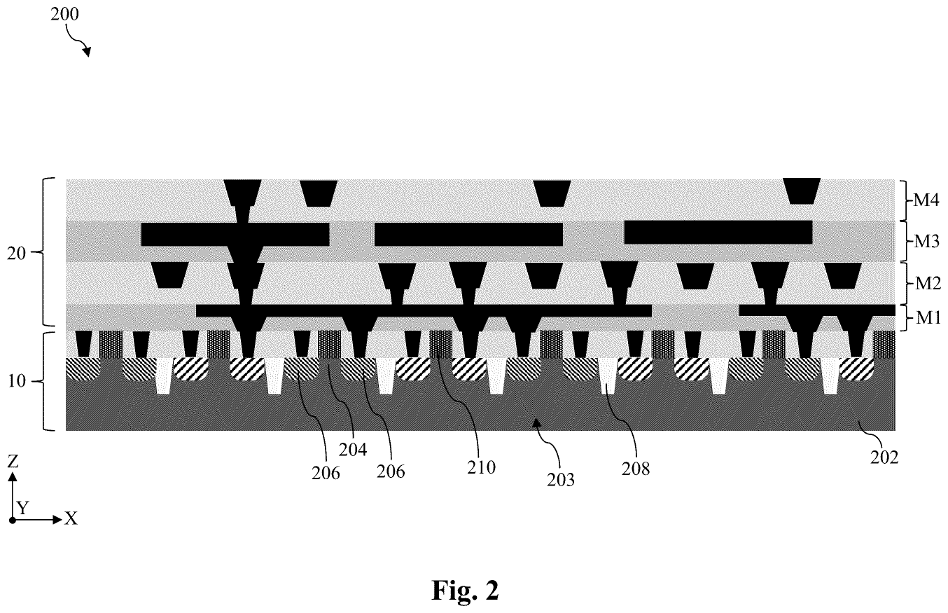

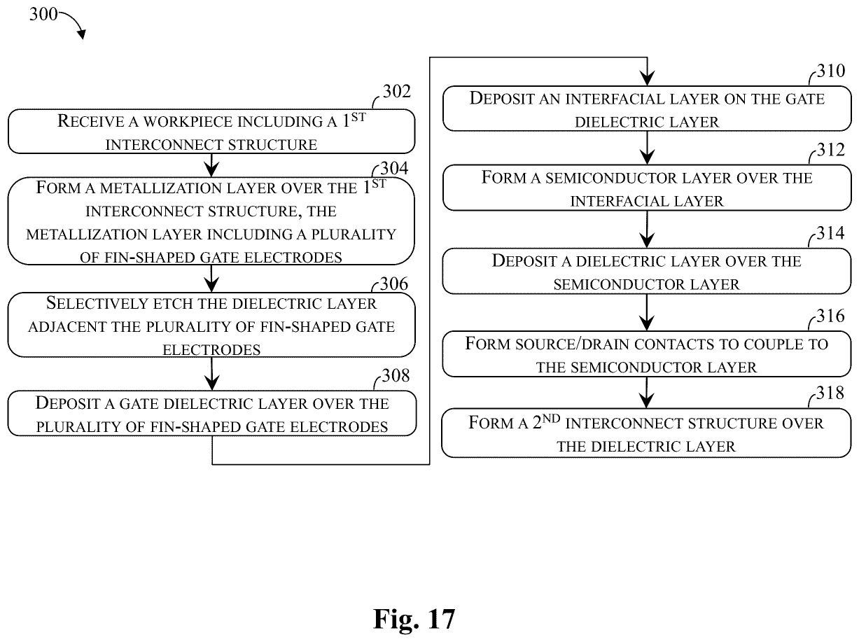

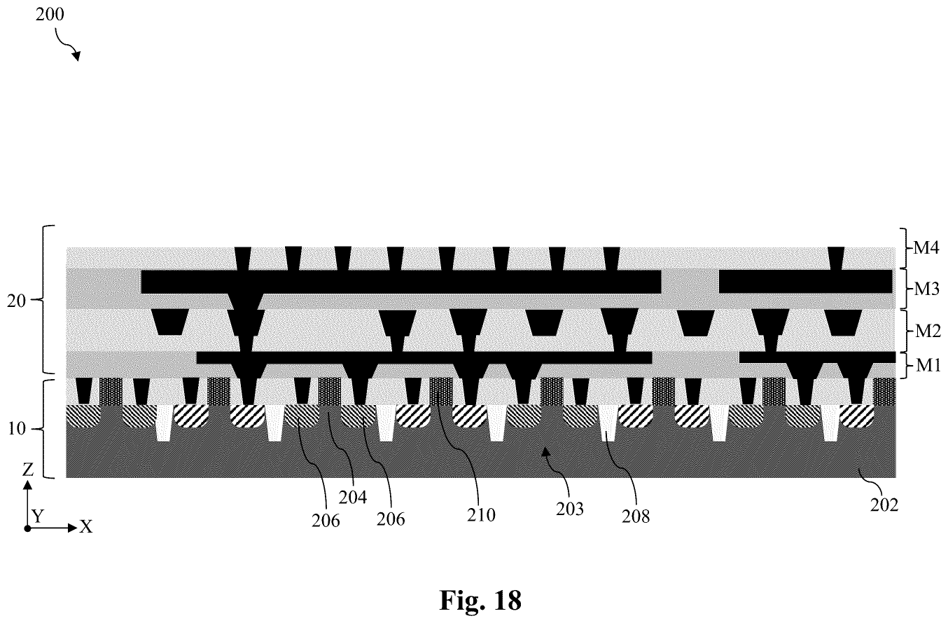

The various aspects of the present disclosure will now be described in more detail with reference to the figures. FIGS. 1 and 17 include flowcharts of methods 100 and 300 for forming a semiconductor device according to embodiments of the present disclosure. Methods 100 and 300 are merely examples and are not intended to limit the present disclosure to what is explicitly illustrated in methods 100 and 300. Additional steps can be provided before, during and after method 100 or method 300, and some steps described can be replaced, eliminated, or moved around for additional embodiments of the methods. Not all steps are described herein in detail for reasons of simplicity. Method 100 is described below in conjunction with FIGS. 2-12, which include fragmentary cross-sectional views of a workpiece 200 at different stages of fabrication according to embodiments of method 100. Method 300 is described below in conjunction with FIGS. 18-29, which include fragmentary cross-sectional views of a workpiece 200 at different stages of fabrication according to embodiments of method 300. For avoidance of doubts, throughout the figures, the X direction is perpendicular to the Y direction and the Z direction is perpendicular to both the X direction and the Y direction. Because the workpiece 200 will be formed into a semiconductor device upon conclusion of its fabrication process, the workpiece 200 may be referred to as a semiconductor device 200 or a semiconductor structure 200 as the context requires.

Referring to FIGS. 1 and 2, method 100 includes a block 102 where a workpiece 200 is received. As shown in FIG. 2, the workpiece 200 may include a device substrate 10 and a first interconnect structure 20 disposed over the device substrate 10. The device substrate 10 may include a semiconductor substrate 202 and transistors 203 on the semiconductor substrate 202. The semiconductor substrate 202 may be a silicon (Si) substrate. In some other embodiments, the semiconductor substrate 202 may include other semiconductors such as germanium (Ge), silicon germanium (SiGe), or a III-V semiconductor material. Example III-V semiconductor materials may include gallium arsenide (GaAs), indium phosphide (InP), gallium phosphide (GaP), gallium nitride (GaN), gallium arsenide phosphide (GaAsP), aluminum indium arsenide (AlInAs), aluminum gallium arsenide (AlGaAs), gallium indium phosphide (GaInP), and indium gallium arsenide (InGaAs). The semiconductor substrate 202 may also include an insulating layer, such as a silicon oxide layer, to have a silicon-on-insulator (SOI) structure.

Each of the transistors 203 may be a multi-gate device. Here, a multi-gate device generally refers to a device having a gate structure, or portion thereof, disposed over more than one side of a channel region. Fin-like field effect transistors (FinFETs) and gate-all-around (GAA) transistors are examples of multi-gate devices that have become popular and promising candidates for high performance and low leakage applications. A FinFET has an elevated channel wrapped by a gate on more than one side (for example, the gate wraps a top and sidewalls of a “fin” of semiconductor material extending from a substrate). A GAA transistor has a gate structure that can extend, partially or fully, around a channel region to provide access to the channel region on two or more sides. Because its gate structure surrounds the channel regions, GAA transistor may also be referred to as a surrounding gate transistor (SGT) or a multi-bridge-channel (MBC) transistor. The channel region of a GAA transistor may take form of nanowires, nanosheets, or other nanostructures and for that reasons, a GAA transistor may also be referred to as a nanowire transistor or a nanosheet transistor. As shown in FIG. 2, each of the transistors 203 includes a channel region 204 extending between two source/drain features 206 along the X direction. A gate structure 210 disposed over the channel region 204. The transistors 203 may be spaced apart from one another by isolation features 208. While not explicitly shown in FIG. 2, when the transistor 203 is a GAA transistor, the channel region 204 includes multiple channel members extending between the two source/drain features 206 along the X direction and the gate structure 210 wraps around each of the multiple channel members in the channel region 204.

The first interconnect structure 20 shown in FIG. 2 may be part of an interconnect structure that also includes a second interconnect structure 30 (to be described below). In this regard, the first interconnect structure 20 is disposed below the back-end active devices and the second interconnect structure 30 is disposed over the back-end active devices. The first interconnect structure 20 and the second interconnect structure 30 as a whole may include between about 8 and about 15 metallization layers, each of which includes contact vias and conductive lines embedded in an intermetal dielectric (IMD) layer. The contact vias and conductive lines may include copper, titanium nitride, or a combination thereof. Because the lower metallization layers closer to the device substrate 10 are usually too crowded to accommodate back-end devices, the first interconnect structure 20 may include 4 to 12 metallization layers. In the depicted example, the first interconnect structure 20 includes 4 metallization layers—M1, M2, M3 and M4.

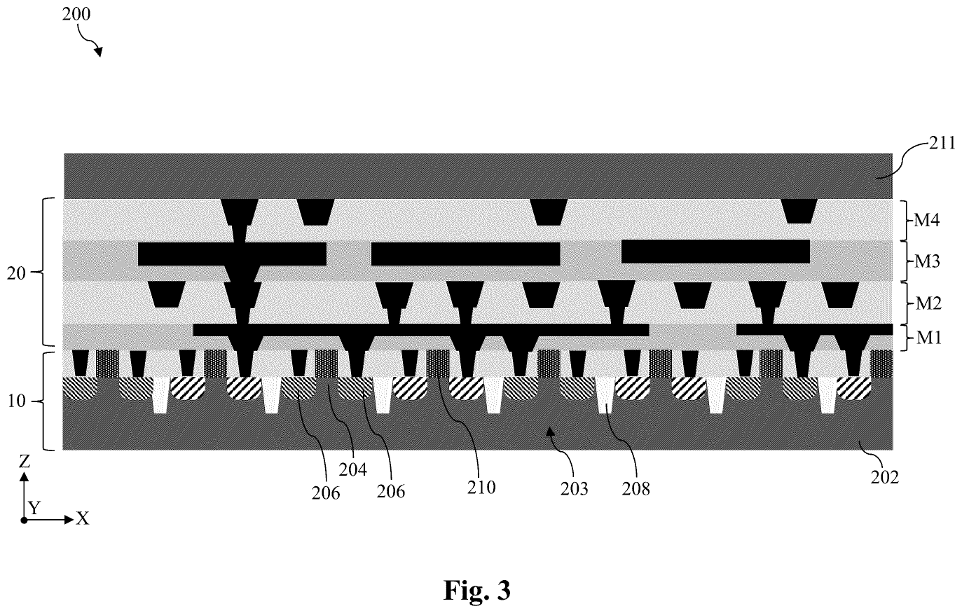

Referring to FIGS. 1 and 3, method 100 includes a block 104 where a dielectric spacer layer 211 is deposited over the workpiece 200. In some embodiments, the dielectric spacer layer 211 may include silicon oxide, silicon nitride, silicon oxynitride, or silicon oxycarbonitride. In some implementations, the dielectric spacer layer 211 may be deposited using chemical vapor deposition (CVD) or a suitable deposition method. In some instances, the dielectric spacer layer 211 may have a thickness between about 30 nm and about 200 nm, which may account for about one half of the IMD layer of the topmost metallization layer of the first interconnect structure 20.

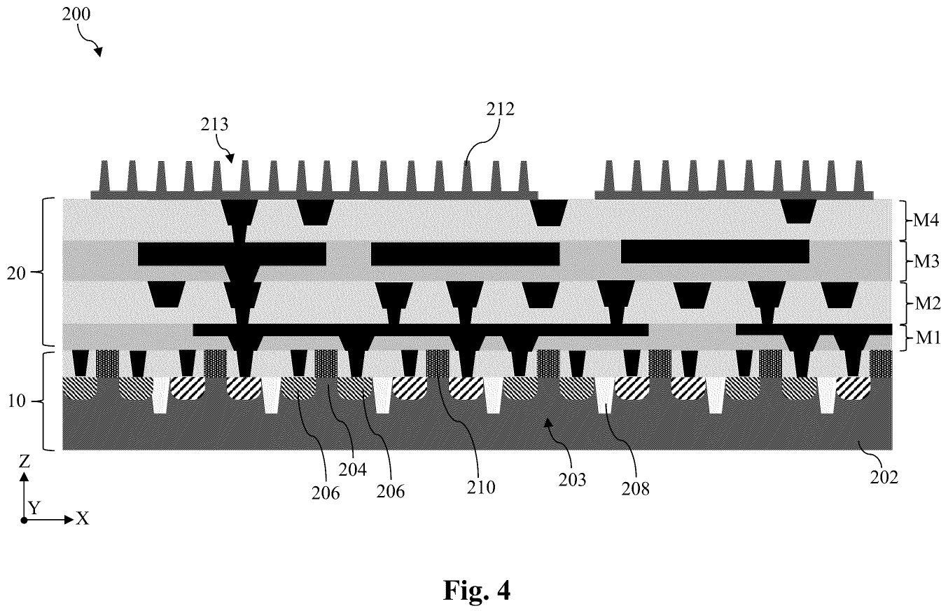

Referring to FIGS. 1 and 4, method 100 includes a block 106 where the dielectric spacer layer 211 is patterned to form fin-shaped structures 212. At block 106, photolithography processes and etching processes are used to pattern the dielectric spacer layer 211. As shown in FIG. 4, the dielectric spacer layer 211 may be divided into multiple sections and each section is patterned to have wavy structures to increase the surface area. In the depicted embodiments, the dielectric spacer layer 211 is patterned to form trenches 213 that define fin-shaped structures 212. In some instances, the trenches 213 do not extend through the dielectric spacer layer 211 such that the fin-shaped structures 212 rise from a base dielectric spacer layer 211. As shown in FIG. 4, the trenches 213 and the fin-shaped structures 212 form a wavy dielectric spacer structure that provides three-dimensional (3D) topography to increase channel areas.

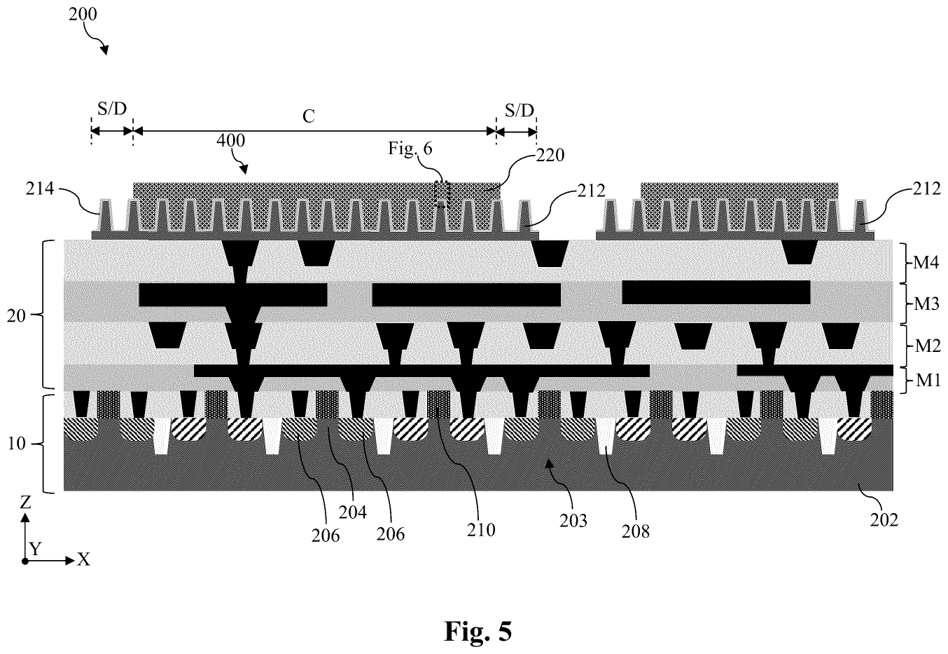

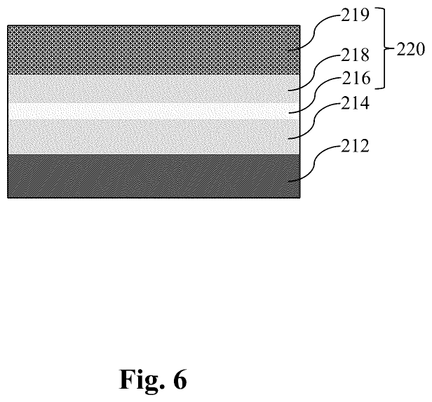

Referring to FIGS. 1, 5 and 6, method 100 includes a block 108 where a semiconductor layer 214 is deposited over the fin-shaped structures 212. In some embodiments, the semiconductor layer 214 may be a two-dimensional (2D) or low-dimensional semiconductor layer that may be formed or transferred over the fin-shaped structure 212 at a temperature that does not cause substantial harm to the front-end structures. Example semiconductor materials for the semiconductor layer 214 may include molybdenum sulfide (MoS₂), tungsten selenide (WSe₂), cuprous oxide (Cu₂O), carbon nanotube (CNT), indium oxide (InO), or indium gallium zinc oxide (IGZO). In some implementations, the semiconductor layer 214 may be synthesized or grown on a growth substrate, such as a sapphire substrate, a crystalline copper substrate, a diamond substrate, a silicon substrate, or a silicon oxide substrate and then the semiconductor layer 214 is transferred onto the fin-shaped structures 212. In some alternative embodiments, the semiconductor layer 214 may be deposited on the fin-shaped structures 212 using atomic layer deposition (ALD). The semiconductor layer 214 may transferred or deposited on the fin-shaped structures 212 at a process temperature between about 150° and about 400° C. In order to show the semiconductor layer 214 and the layer deposited thereon in more details, a portion of the fin-shaped structures 212 are enlarged and illustrated in FIG. 6. In some implementations, the semiconductor layer 214 may be conformally deposited over surfaces of the fin-shaped structure 212, including surfaces exposed in the trenches 213. In some instances, the semiconductor layer 214 may have a thickness between about 0.5 nm and about 10 nm. In some embodiments not explicitly shown in the figures, photoresist features or bottom antireflective coating (BARC) features may be formed over the semiconductor layer 214 to define a gate opening over the channel region C while designated source/drain regions (S/D) of the semiconductor layer 214 are covered. As will be described further below, when the source/drain regions (S/D) sandwich the channel region C along the propagation direction of the fin-shaped structures 212 (X direction in FIG. 5), the resulting back-end device has a long channel length along the topography of the fin-shaped structures 212 and may be referred to as in a low-leakage configuration. When the source/drain regions (S/D) sandwich the channel region C along the lengthwise direction of the fin-shaped structures 212 (Y direction in FIG. 5), the resulting back-end device has a large channel width and may be referred to as in a high drive current configuration.

Referring to FIGS. 1, 5 and 6, method 100 includes a block 110 where gate structure 220 is formed over the semiconductor layer 214. To better illustrate the layers in the gate structure 220, a part of the gate structure 220 in FIG. 5 is enlarged and shown in FIG. 6. In some embodiments represented in FIG. 6, the gate structure 220 includes an interfacial layer 216 on the semiconductor layer 214, a gate dielectric 218 over the interfacial layer 216, and a gate electrode layer 219 over the gate dielectric layer 218. In embodiments where a gate opening is defined by photoresist features or BARC features in the channel region C, the interfacial layer 216, the gate dielectric layer 218 and the gate electrode layer 219 are deposited over the gate opening. The interfacial layer 216 may include silicon oxide, van der Waals (VDW) air gap, aluminum oxide, or titanium oxide and may be deposited using ALD, CVD or a suitable method. The VDW air gap refers to the air gap formed when the semiconductor layer 214 is transferred on the fin-shaped structures 212. In some instances, the interfacial layer 216 may have a thickness between about 0.5 nm and about 1 nm. In some embodiments, the gate dielectric layer 218 may include hafnium oxide, zirconium oxide, hafnium zirconium oxide, or a sandwich structure that includes hafnium oxide and zirconium oxide and may be deposited using CVD or a suitable method. Material for the gate dielectric layer 218 may be referred to as a high-k dielectric material as its dielectric constant is greater than that of silicon oxide, which is about 3.9. In some instances, the gate dielectric layer 218 may between about 1.5 nm and about 3.5 nm. The gate electrode layer 219 may include titanium nitride (TiN), tantalum nitride (TaN), tungsten (W), ruthenium (Ru), or copper (Cu) and may be deposited using physical vapor deposition (PVD), CVD, or a suitable method. After the deposition of the interfacial layer 216, the gate dielectric layer 218, and the gate electrode layer 219, a planarization process, such as a chemical mechanical polishing (CMP) process, is then performed to remove excess materials over the photoresist features or BARC features. After the planarization, the photoresist features or BARC features are selectively removed by ashing or selective etching to form the gate structure 220 shown in FIG. 5. After the formation of the gate structure 220, a first back-end transistor 400 is formed.

It is noted that the thickness ranges for the semiconductor layer 214, the interfacial layer 216, and the gate dielectric layer 218 in the first back-end transistor 400 (as well as other back-end transistors described in the present disclosure) are not trivial and are selected to be similar to their counterparts in the transistor 203. The first back-end transistor 400 (as well as other back-end transistors described in the present disclosure) has substantially the same effective gate dielectric layer thickness as the transistors 203. In other words, the first back-end transistor 400 (as well as other back-end transistors described in the present disclosure) has the same threshold voltage as the transistors 203. The differences between the first back-end transistor 400 and the transistor 203 lie in their locations and effective channel widths. The first back-end transistor 400 (as well as other back-end transistors described in the present disclosure) is located in the BEOL level, such as the interconnect structures. Due to the enlarged device area or footprint and the wavy structures, the first back-end transistor 400 has a much greater channel width than the transistor 203. As a result, the first back-end transistor 400 (as well as other back-end transistors described in the present disclosure) has much greater drive current than the transistor 203.

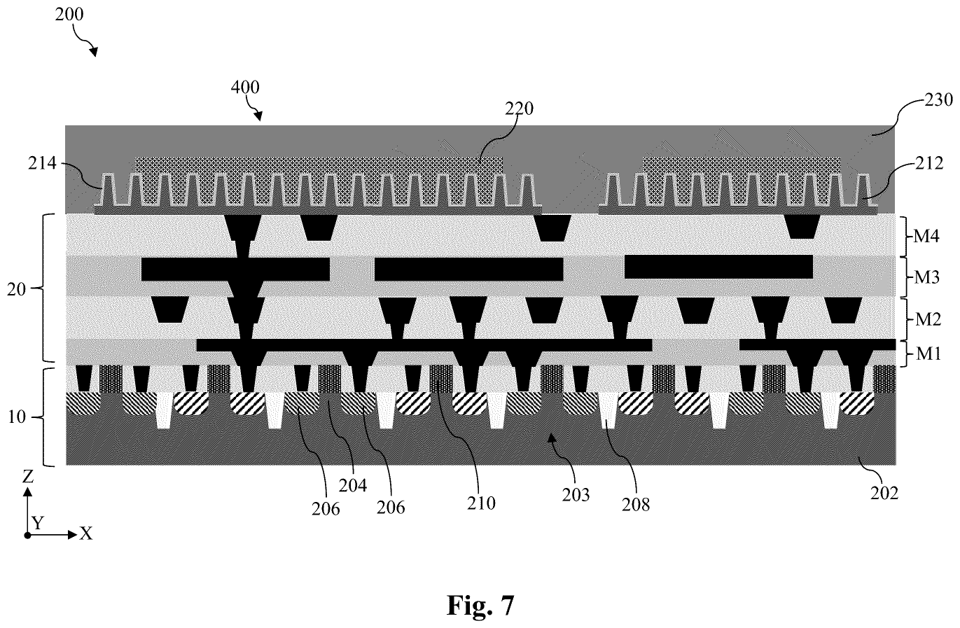

Referring to FIGS. 1 and 7, method 100 includes a block 112 where a dielectric layer 230 is deposited over the gate structure 220. After the formation of the gate structure 220, the dielectric layer is deposited over the workpiece 200 using spin-on coating or flowable CVD (FCVD). The dielectric layer 230 may include tetraethylorthosilicate (TEOS) oxide, un-doped silicate glass, or doped silicon oxide such as borophosphosilicate glass (BPSG), fused silica glass (FSG), phosphosilicate glass (PSG), boron doped silica glass (BSG), undoped silica glass (USG), and/or other suitable dielectric materials. Material for the dielectric layer 230 may be referred to as a low-k dielectric material as its dielectric constant is smaller than that of silicon oxide, which is about 3.9.

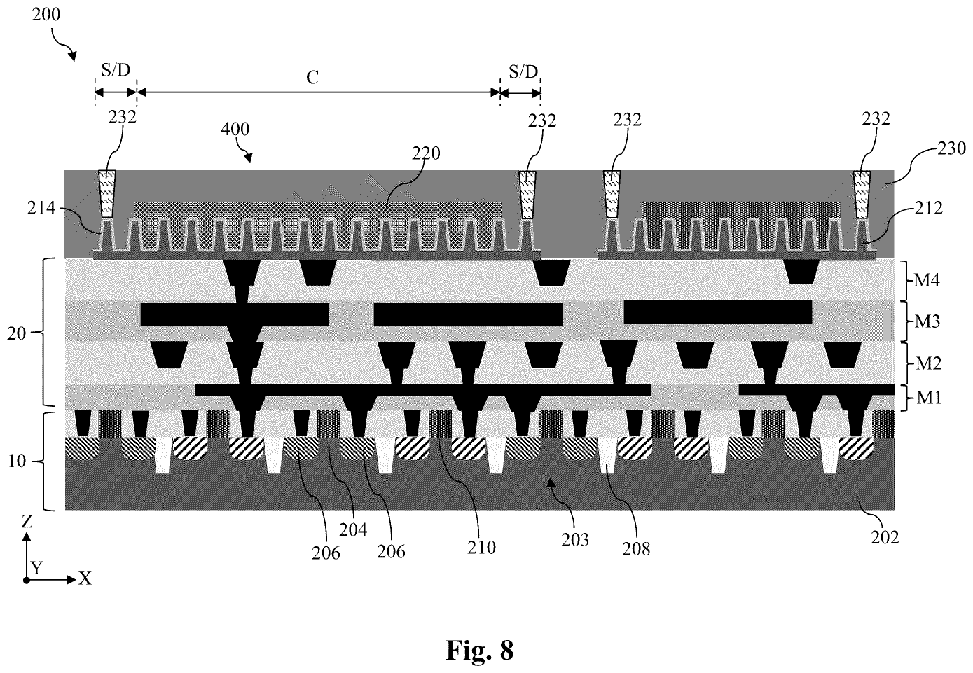

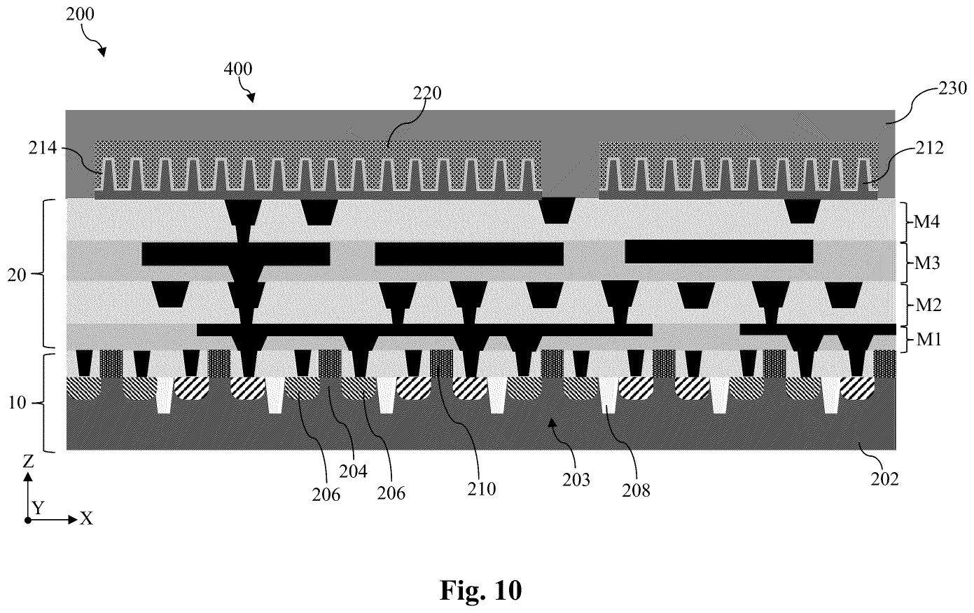

Referring to FIGS. 1 and 8-11, method 100 includes a block 114 where source/drain contacts 232 are formed to couple to the semiconductor layer 214. As briefly explained above, back-end devices of the present disclosure may be either in a low leakage configuration or a high drive current configuration. When low leakage is desired, a length of the channel region C is parallel to a propagation direction of the fin-shaped structures 212. When high drive current is desired, a length of the channel region C is parallel to a lengthwise direction of the fin-shaped structures 212. FIG. 8 illustrates a low leakage configuration and FIG. 10 illustrates a high drive current configuration. The channel region C in FIG. 8 is sandwiched between source/drain regions (S/D) along the X direction. Along the X direction, the channel length tracks the topography of the fin-shaped structures 212 in the channel region C and is therefore maximized. This extended channel length shown in FIG. 8 helps reduce leakage. The channel region C in FIG. 10 is sandwiched between source/drain regions (S/D) along the Y direction. Along the X direction, the channel width tracks the topography of the fin-shaped structures 212 in the channel region C and is therefore maximized. This increased channel width shown in FIG. 10 helps increase drive current.

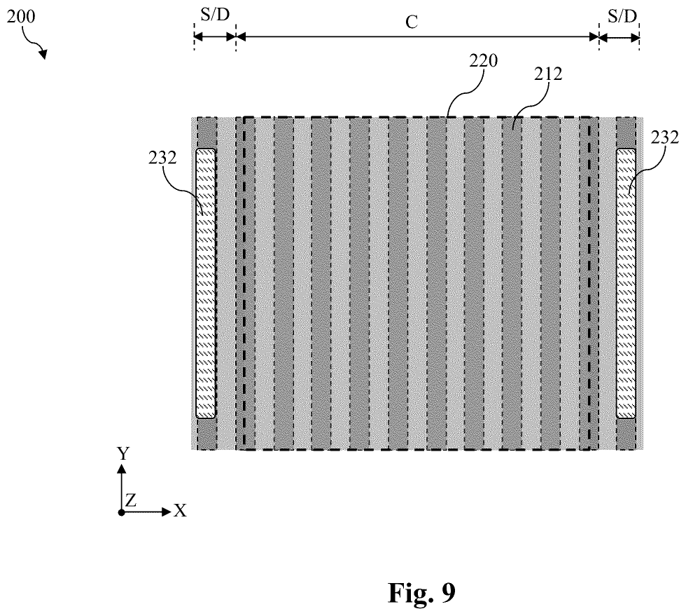

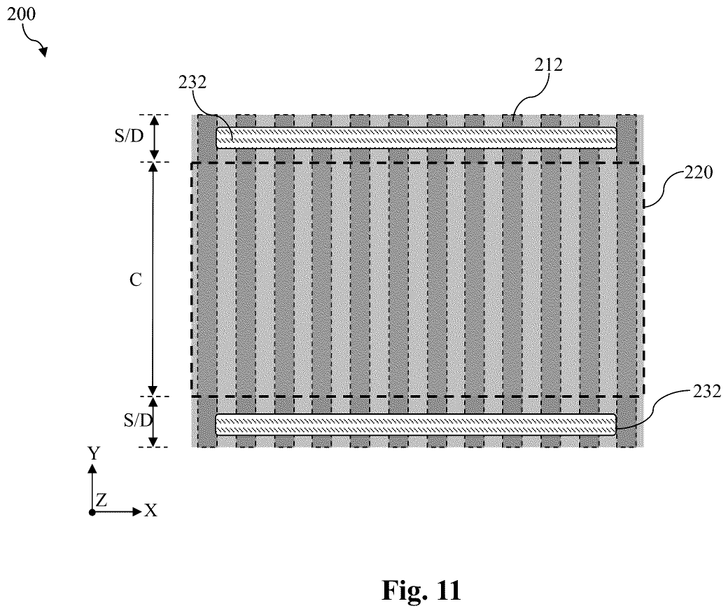

In an example process to form source/drain contacts 232, source/drain contact openings are formed through the dielectric layer 230 to expose the semiconductor layer 214 in the source/drain region (S/D). A metal fill layer is than deposited in the source/drain contact openings to form the source/drain contacts 232. In some embodiments, the metal fill layer may include beryllium (Be), nickel (Ni), platinum (Pt), gold (Au), yttrium (Y), ytterbium (Yb), titanium nitride (TiN), tantalum nitride (TaN), tungsten (W), or a combination thereof and may be deposited using PVD or CVD. Referring to FIG. 9, in embodiments where the low leakage configuration is desired, each of the source/drain contacts 232 is elongated along the Y direction, in parallel with the fin-shaped structures 212. Referring to FIG. 11, in embodiments where high drive current configuration is desired, each of the source/drain contacts 232 is elongated along the X direction, perpendicular to the lengthwise direction of the fin-shaped structures 212.

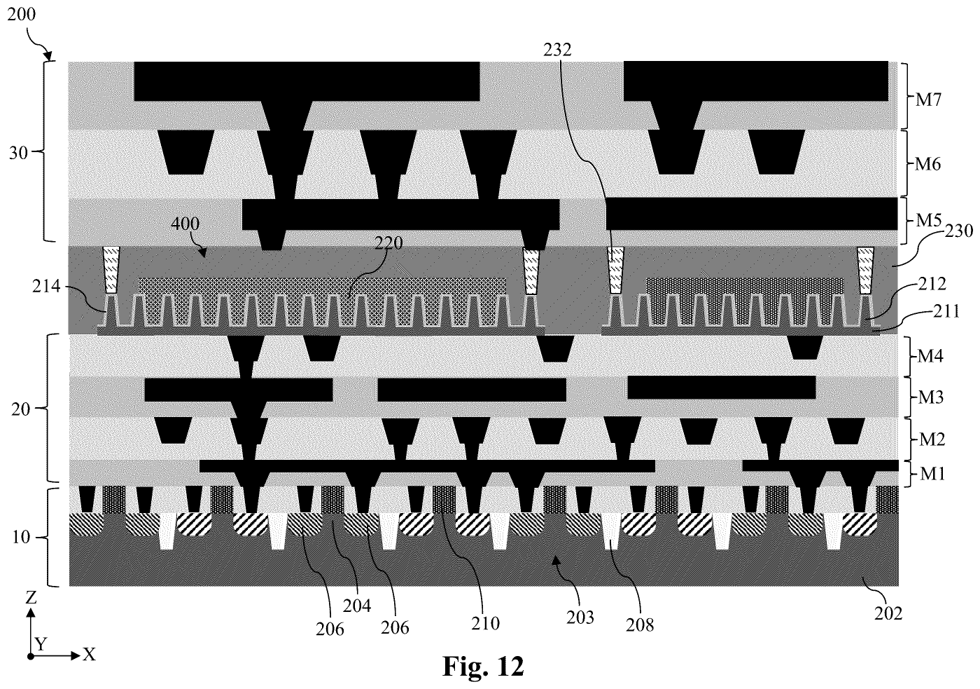

Referring to FIGS. 1 and 12, method 100 includes a block 116 where a second interconnect structure 30 is formed over the dielectric layer 230. In some embodiments, both the first interconnect structure 20 below the first back-end transistor 400 and the second interconnect structure 30 above the first back-end transistor 400 are parts of an interconnect structures. The second interconnect structure 30 may include between 4 and 10 metallization layers, each of which includes contact vias and conductive lines embedded in an intermetal dielectric (IMD) layer. In some embodiments where the first back-end transistor 400 is formed on the topmost metallization layer, operations at block 116 may be omitted and the workpiece 200 does not include the second interconnect structure 30. In those embodiments, the first interconnect structure 20 is the only frontside interconnect structure.

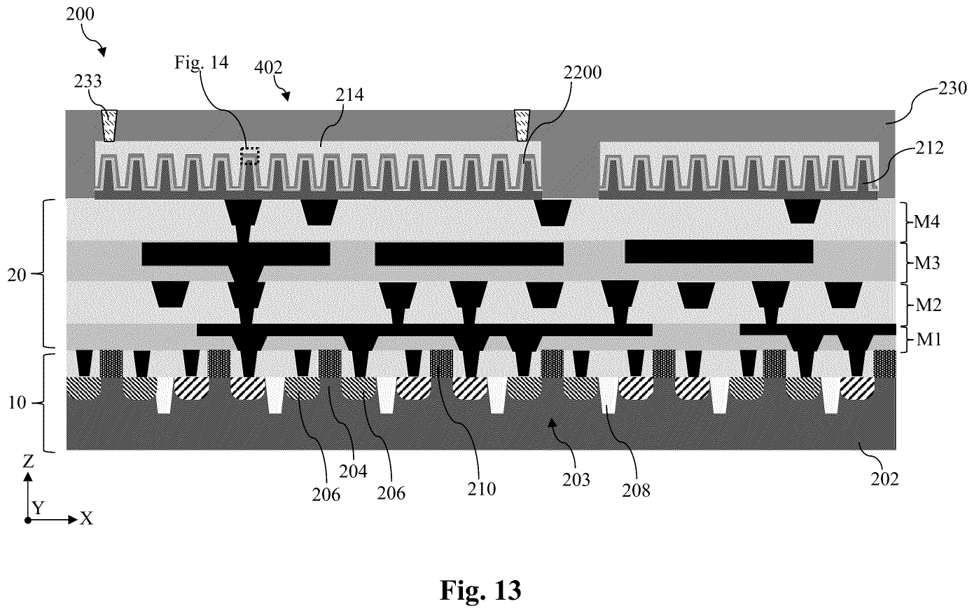

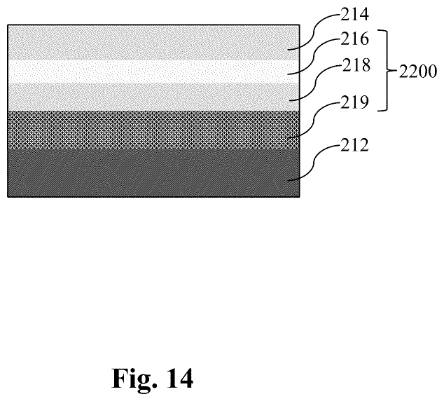

As described above, the first back-end transistor 400 may be formed when operations at block 108 of method 100 are performed before operations at block 110. As a result, the gate structure 220 is disposed over the semiconductor layer 214. Because the gate structure 220 is disposed over the semiconductor layer 214, the first back-end transistor 400 may be referred to as a top gate structure 220. In some alternative embodiments shown in FIGS. 13 and 14, operations at block 110 may be performed before operations at block 108. FIG. 13 illustrates a semiconductor structure 200 where a first back gate structure 2200 is formed over the fin-shaped structure 212 before the formation of the semiconductor layer 214. To better illustrate the various layers in the first back gate structure 2200, a portion of FIG. 13 is enlarged and illustrated in FIG. 14. As shown in FIG. 14, the first back gate structure 2200 is formed over the fin-shaped structure 212 and the semiconductor layer 214 is disposed on the first back gate structure 2200. The first back gate structure 2200 includes a gate electrode layer 219 disposed directly on the fin-shaped structure 21, a gate dielectric layer 218 disposed directly on the gate electrode layer 219, and an interfacial layer 216 disposed directly on the gate dielectric layer 218. The semiconductor layer 214 is then deposited on the interfacial layer 216. Materials and depositions methods of the gate electrode layer 219, the gate dielectric layer 218, the interfacial layer 216, and the semiconductor layer 214 have been described above and will not be repeated here. As shown in FIG. 13, because the semiconductor layer 214 is now above the first back gate structure 2200, source/drain contacts 233 may land directly on the semiconductor layer 214. For case of reference, the back-end transistor illustrated in FIGS. 13 and 14 may be referred to as a second back-end transistor 402.

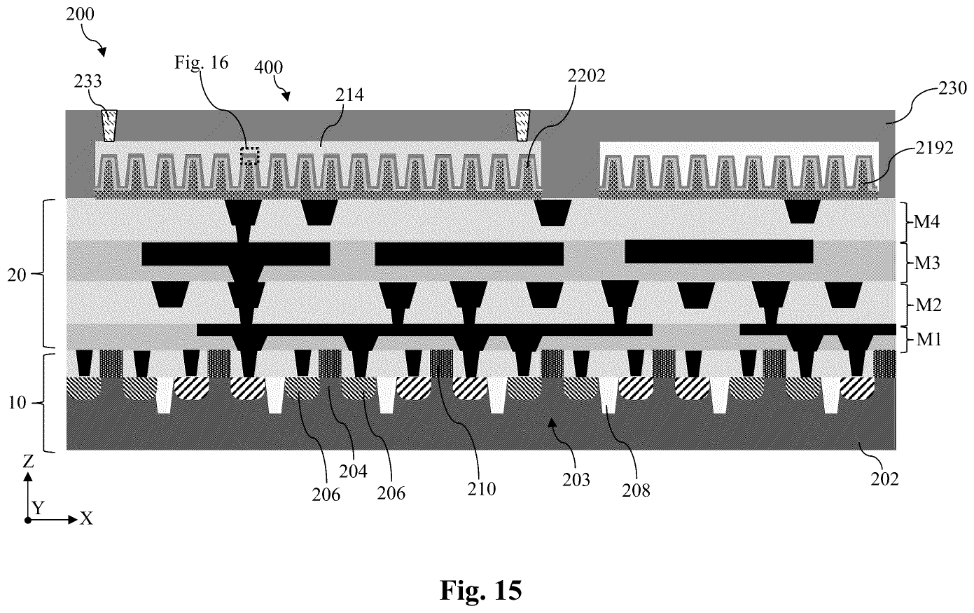

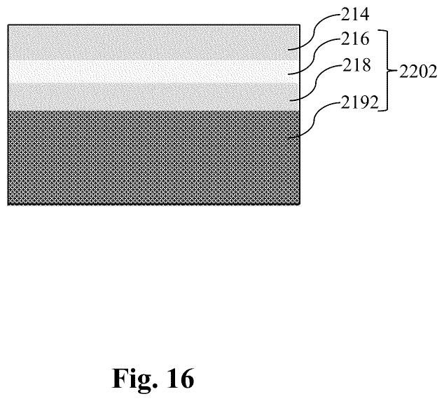

In still some embodiments illustrated in FIGS. 15 and 16, the gate electrode layer 219 is deposited and patterned to form a wavy gate electrode 2192 that includes metal fin-shaped structures similar to the fin-shaped structures 212 shown in FIG. 4. To better illustrate details, a portion of FIG. 15 is enlarged and illustrated in FIG. 16. After formation of the wavy gate electrode 2192, a gate dielectric layer 218 is deposited over the wavy gate electrode 2192. Then an interfacial layer 216 is deposited over the gate dielectric layer 218. A semiconductor layer 214 is deposited over the interfacial layer. Materials and depositions methods of the gate dielectric layer 218, the interfacial layer 216, and the semiconductor layer 214 have been described above and will not be repeated here. The wavy gate electrode 2192 shares the same composition with the gate electrode layer 219. For ease of reference, the wavy gate electrode 2192, the gate dielectric layer 218, and the interfacial layer 216 may be collectively referred to as a second back gate structure 2202.

The patterning of the dielectric space layer at block 106 of method 100 includes use of photolithography processes to form fin-shaped structure 212. In some alternative embodiments, such as method 300 in FIG. 17, self-aligned etching processes may be incorporated to reduce the complexity of the photolithography processes and the photomasks used in the photolithography processes.

Referring to FIGS. 17 and 18, method 300 includes a block 302 where a workpiece 200 is received. As shown in FIG. 2, the workpiece 200 may include a device substrate 10 and a first interconnect structure 20 disposed over the device substrate 10. The device substrate 10 may include a semiconductor substrate 202 and transistors 203 on the semiconductor substrate 202. The semiconductor substrate 202 may be a silicon (Si) substrate. In some other embodiments, the semiconductor substrate 202 may include other semiconductors such as germanium (Ge), silicon germanium (SiGe), or a III-V semiconductor material. Example III-V semiconductor materials may include gallium arsenide (GaAs), indium phosphide (InP), gallium phosphide (GaP), gallium nitride (GaN), gallium arsenide phosphide (GaAsP), aluminum indium arsenide (AlInAs), aluminum gallium arsenide (AlGaAs), gallium indium phosphide (GaInP), and indium gallium arsenide (InGaAs). The semiconductor substrate 202 may also include an insulating layer, such as a silicon oxide layer, to have a silicon-on-insulator (SOI) structure.

Each of the transistors 203 may be a multi-gate device. Here, a multi-gate device generally refers to a device having a gate structure, or portion thereof, disposed over more than one side of a channel region. Fin-like field effect transistors (FinFETs) and gate-all-around (GAA) transistors are examples of multi-gate devices that have become popular and promising candidates for high performance and low leakage applications. A FinFET has an elevated channel wrapped by a gate on more than one side (for example, the gate wraps a top and sidewalls of a “fin” of semiconductor material extending from a substrate). A GAA transistor has a gate structure that can extend, partially or fully, around a channel region to provide access to the channel region on two or more sides. Because its gate structure surrounds the channel regions, GAA transistor may also be referred to as a surrounding gate transistor (SGT) or a multi-bridge-channel (MBC) transistor. The channel region of a GAA transistor may take form of nanowires, nanosheets, or other nanostructures and for that reasons, a GAA transistor may also be referred to as a nanowire transistor or a nanosheet transistor. As shown in FIG. 2, each of the transistors 203 includes a channel region 204 extending between two source/drain features 206 along the X direction. A gate structure 210 disposed over the channel region 204. The transistors 203 may be spaced apart from one another by isolation features 208. While not explicitly shown in FIG. 2, when the transistor 203 is a GAA transistor, the channel region 204 includes multiple channel members extending between the two source/drain features 206 along the X direction and the gate structure 210 wraps around each of the multiple channel members in the channel region 204.

The first interconnect structure 20 shown in FIG. 2 may be part of an interconnect structure that also includes a second interconnect structure 30 (to be described below). In this regard, the first interconnect structure 20 is disposed below the back-end active devices and the second interconnect structure 30 is disposed over the back-end active devices. The first interconnect structure 20 and the second interconnect structure 30 as a whole may include between about 8 and about 15 metallization layers, each of which includes contact vias and conductive lines embedded in an intermetal dielectric (IMD) layer. Because the lower metallization layers closer to the device substrate 10 are usually too crowded to accommodate back-end devices, the first interconnect structure 20 may include 4 to 5 metallization layers. In the depicted example, the first interconnect structure 20 includes 4 metallization layers—M1, M2, M3, and M4.

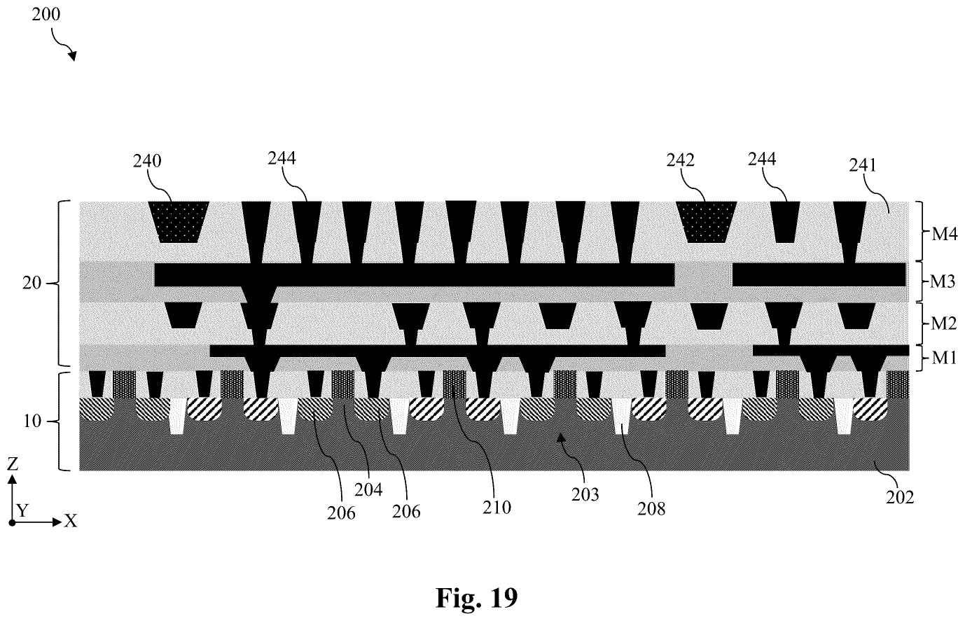

Referring to FIGS. 17 and 19, method 300 includes a block 304 where a metallization layer is formed over the first interconnect structure 20. As shown in FIG. 19, the metallization layer formed at block 304 may be part of the M4 metallization layer M4. The metallization layer in FIG. 19 includes an IMD layer 241 and a power pad 240, a virtual power pad 242, and a plurality of fin-shaped gate electrodes 244 embedded in the IMD layer 241. In some embodiments, the power pad 240, the virtual power pad 242, and the plurality of fin-shaped gate electrodes 244 include titanium nitride (TiN), tantalum nitride (TaN), tungsten (W), ruthenium (Ru), or copper (Cu). In some implementations, the power pad 240 is electrically coupled to a positive supply voltage (Vdd) and the virtual power pad 242 is electrically coupled to logic circuits embodied using the transistors 203. Each of the plurality of fin-shaped gate electrodes 244 extends lengthwise along the Y direction.

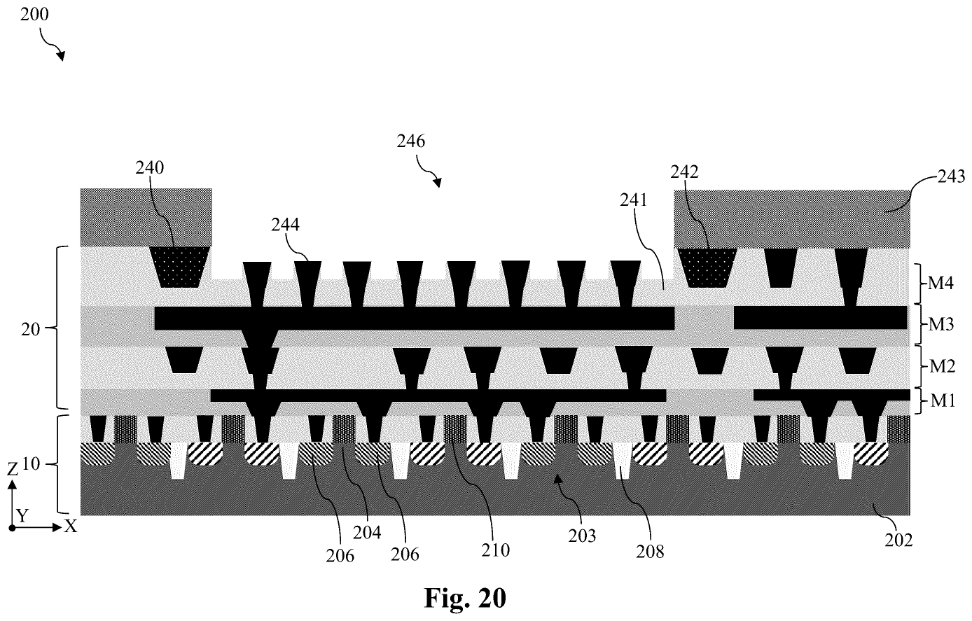

Referring to FIGS. 17 and 20, method 300 includes a block 306 where the IMD layer 241 in the metallization layer is selectively etched back to expose the fin-shaped structures gate electrodes 244. Operations at block 306 form a gate trench 246. In order to form the gate trench 246, a patterned mask 243 is formed over the metallization layer formed at block 304. The patterned mask 243 may include a patterned photoresist layer or a patterned BARC layer. In some embodiments not explicitly shown in FIG. 20, one or more hard mask layer may be deposited over the workpiece 200 before the deposition of the patterned mask 243. In some embodiments represented in FIG. 20, the patterned mask 243 completely covers the power pad 240 and the virtual power pad 242. While the etching process at block 306 is selective to the IMD layer 241, it also recesses the plurality of fin-shaped gate electrodes 244 to reduce their heights. In some embodiments, the etching process at block 306 may include a dry etch process that includes use of an oxygen-containing gas, hydrogen, nitrogen, a fluorine-containing gas (e.g., NF₃, CF₄, SF₆, CH₂F₂, CHF₃, and/or C₂F₆), a chlorine-containing gas (e.g., Cl₂, CHCl₃, CCl₄, and/or BCl₃), a bromine-containing gas (e.g., HBr and/or CHBr₃), an iodine-containing gas (e.g., CF₃I). A shown in FIG. 20, after the etch back, the recessed fin-shaped gate electrodes 244 are exposed and rise above the IMD layer 241.

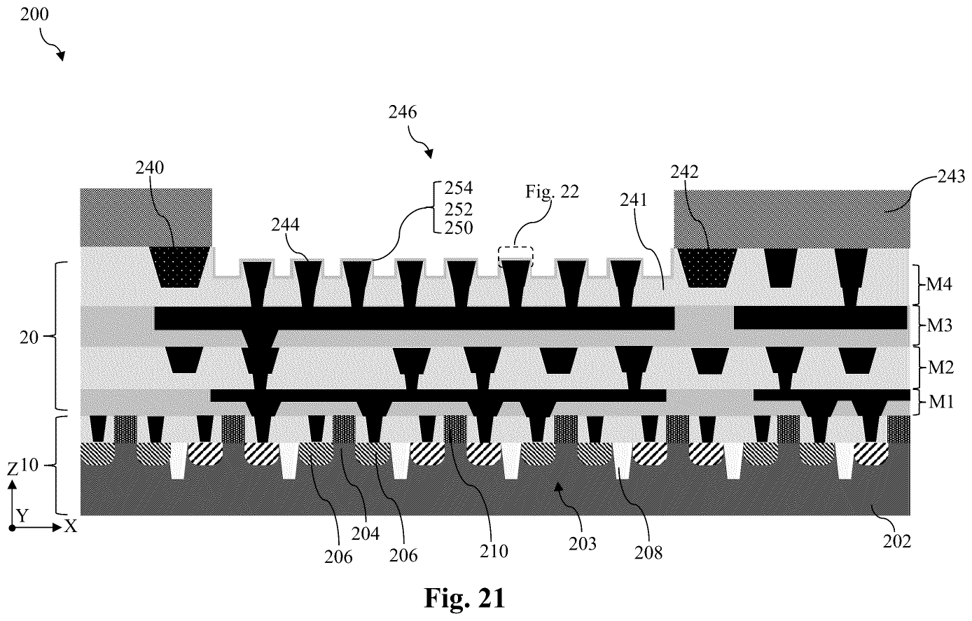

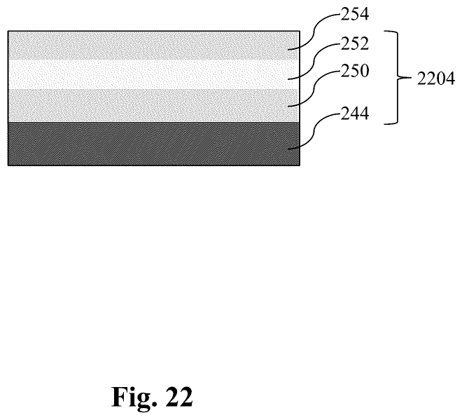

Referring to FIGS. 17, 21 and 22, method 300 includes a block 308 where a gate dielectric layer 250 is deposited over the fin-shaped gate electrodes 244 in the gate trench 246. In some embodiments, the gate dielectric layer 250 may include hafnium oxide, zirconium oxide, hafnium zirconium oxide, or a sandwich structure that includes hafnium oxide and zirconium oxide and may be deposited using CVD or a suitable method. As shown in FIG. 21, the gate dielectric layer 250 is conformally deposited in the gate trench 246, in direct contact with top surfaces of the fin-shaped gate electrodes 244 and exposed surfaces of the IMD layer 241. In order to show the fin-shaped gate electrodes 244 and the layers deposited thereon in more details, a portion of FIG. 21 is enlarged and illustrated in FIG. 22. As illustrated in FIG. 22, the gate dielectric layer 250 is deposited directly on the fin-shaped gate electrodes 244.

Referring to FIGS. 17, 21 and 22, method 300 includes a block 310 where an interfacial layer 252 is deposited over the gate dielectric layer 250. The interfacial layer 252 may include silicon oxide, VDW air gap, aluminum oxide, or titanium oxide and may be deposited using CVD or a suitable method. In some instances, the interfacial layer 252 may have a thickness between about 1.5 nm and about 3.5 nm. In order to show the fin-shaped gate electrodes 244 and the layers deposited thereon in more details, a portion of FIG. 21 is enlarged and illustrated in FIG. 22. As illustrated in FIG. 22, the fin-shaped gate electrodes 244, the gate dielectric layer 250 and the interfacial layer 252 may be referred to as a third back gate structure 2204.

Referring to FIGS. 17, 21 and 22, method 300 includes a block 312 where a semiconductor layer 254 is deposited over the interfacial layer 252. In some embodiments, the semiconductor layer 254 may be a two-dimensional (2D) or low-dimensional semiconductor layer that may be satisfactorily deposited at a temperature that does not cause substantial harm to the front-end structures. Example semiconductor materials for the semiconductor layer 254 may include molybdenum sulfide (MoS₂), tungsten selenide (WSe₂), cuprous oxide (Cu₂O), carbon nanotube (CNT), indium oxide (InO), or indium gallium zinc oxide (IGZO). In order to show the semiconductor layer 254 and the layer deposited thereon in more details, a portion of FIG. 21 is enlarged and illustrated in FIG. 22. In some implementations, the semiconductor layer 254 may be conformally deposited over surfaces of interfacial layer 252 exposed in the gate trench 246. In some instances, the semiconductor layer 254 may have a thickness between about 0.5 nm and about 10 nm.

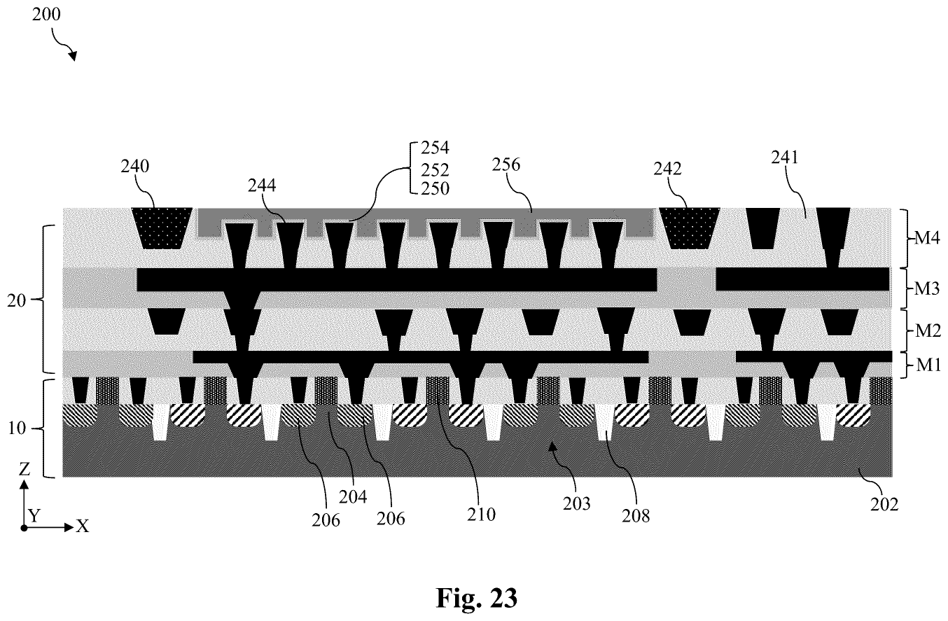

Referring to FIGS. 17 and 23, method 300 includes a block 314 where a dielectric layer 256 is deposited over the semiconductor layer 254. After the deposition of the semiconductor layer 254, the dielectric layer 256 is deposited over the workpiece 200 using spin-on coating or flowable CVD (FCVD). The dielectric layer 256 may include tetraethylorthosilicate (TEOS) oxide, un-doped silicate glass, or doped silicon oxide such as borophosphosilicate glass (BPSG), fused silica glass (FSG), phosphosilicate glass (PSG), boron doped silica glass (BSG), undoped silica glass (USG), and/or other suitable dielectric materials. Material for the dielectric layer 256 may be referred to as a low-k dielectric material as its dielectric constant is smaller than that of silicon oxide, which is about 3.9. After the deposition of the dielectric layer 256, a planarization process, such as a chemical mechanical polishing (CMP) process, is performed to remove excess materials and provide a planar top surface. As shown in FIG. 23, top surfaces of the power pad 240, the gate dielectric layer 250, the interfacial layer 252, the semiconductor layer 254, the dielectric layer 256, the virtual power pad 242, and the IMD layer 241 are coplanar after the planarization process.

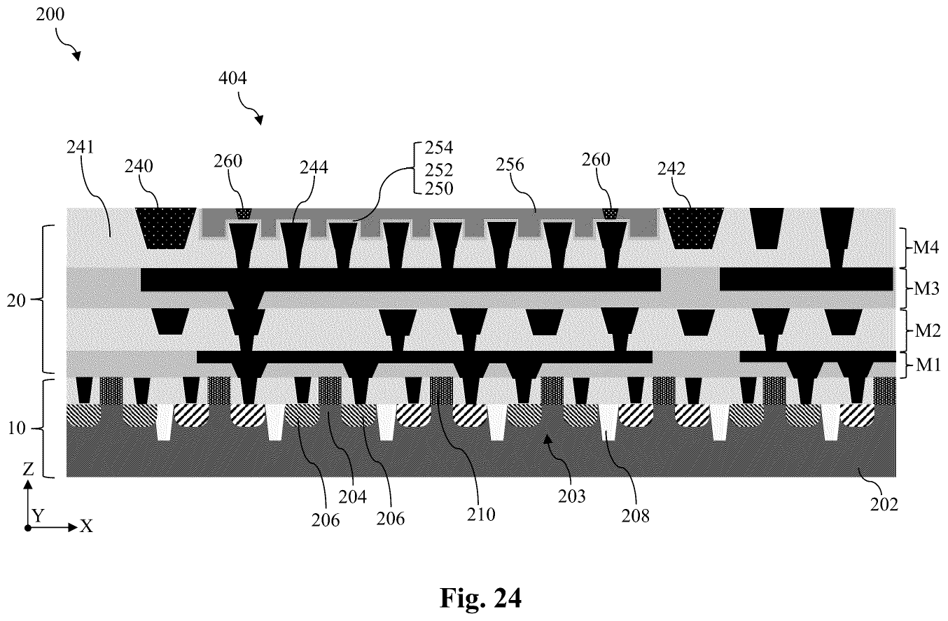

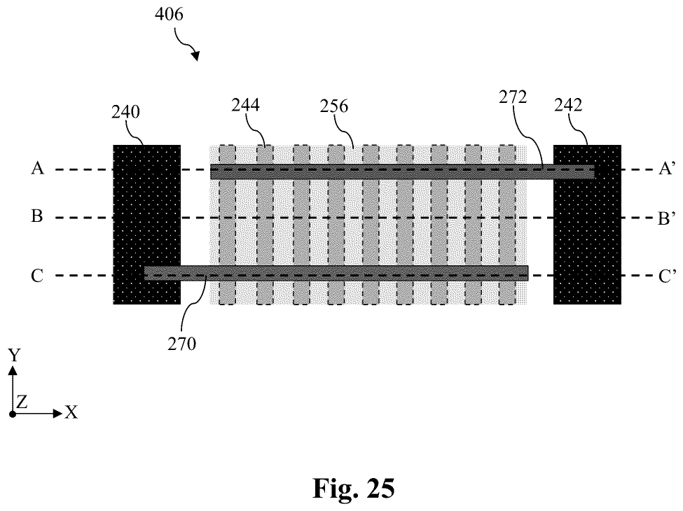

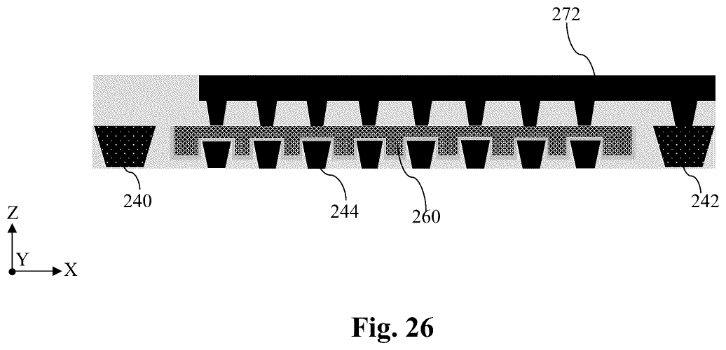

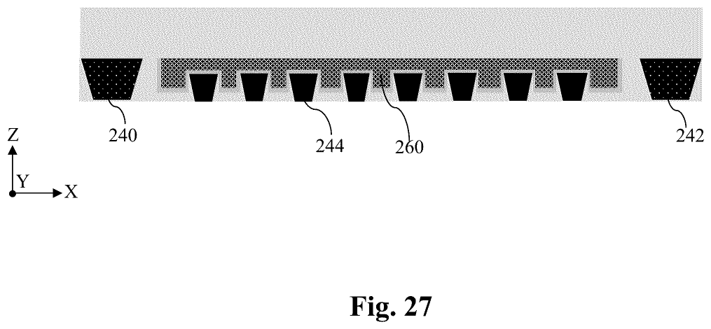

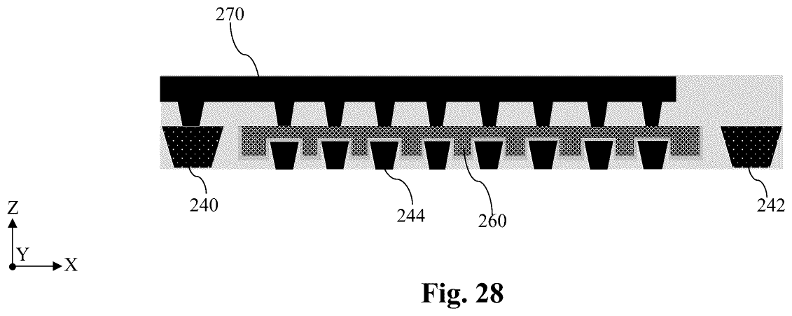

Referring to FIGS. 17 and 24, method 300 includes a block 316 where source/drain contacts 260 are formed to couple to the semiconductor layer 254. In an example process to form source/drain contacts 260, source/drain contact openings are formed through the dielectric layer 256 to expose the semiconductor layer 254 in the source/drain regions. A metal fill layer is than deposited in the source/drain contact openings to form the source/drain contacts 260. In some embodiments, the metal fill layer may include beryllium (Be), nickel (Ni), platinum (Pt), gold (Au), yttrium (Y), ytterbium (Yb), titanium nitride (TiN), tantalum nitride (TaN), tungsten (W), or a combination thereof and may be deposited using PVD or CVD. Referring to FIG. 24, in embodiments where the low leakage configuration is desired, each of the source/drain contacts 260 is elongated along the Y direction, in parallel with the fin-shaped gate electrodes 244. The back-end transistor shown in FIG. 24 may be referred as a third back-end transistor 404. Referring to FIGS. 25-28, in embodiments where high drive current configuration is desired, each of the source/drain contacts 260 is elongated along the X direction, perpendicular to the lengthwise direction of the fin-shaped gate electrodes 244. The back-end transistor shown in FIGS. 25-28 may be referred as a fourth back-end transistor 406. FIG. 25 is a fragmentary top view of the fourth back-end transistor 406. FIGS. 26, 27 and 28 illustrates a fragmentary cross-sectional view along lines A-A′, B-B′ and C-C′. As shown in FIGS. 25 and 27, a metal line 270, along with contact vias connected thereto, electrically couple one of the source/drain contacts 260 to the power pad 240. As shown in FIGS. 25 and 28, another metal line 272, along with contact vias connected thereto, electrically couple the other of the source/drain contacts 260 to the virtual power pad 242.

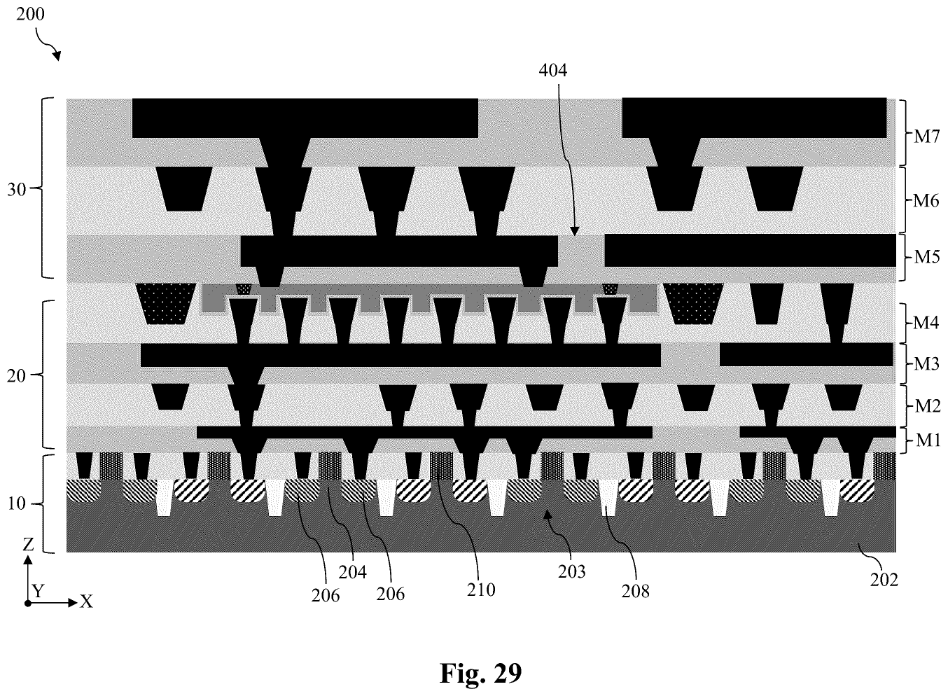

Referring to FIGS. 17 and 29, method 300 includes a block 318 where a second interconnect structure 30 is formed over the dielectric layer 230. In some embodiments, both the first interconnect structure 20 below the third back-end device 404 and the second interconnect structure 30 above the third back-end transistor 404 are parts of an interconnect structures. The second interconnect structure 30 may include between 4 and 10 metallization layers, each of which includes contact vias and conductive lines embedded in an intermetal dielectric (IMD) layer. In some embodiments where the third back-end transistor 404 is formed on the topmost metallization layer, operations at block 318 may be omitted and the workpiece 200 does not include the second interconnect structure 30. In those embodiments, the first interconnect structure 20 is the only frontside interconnect structure.

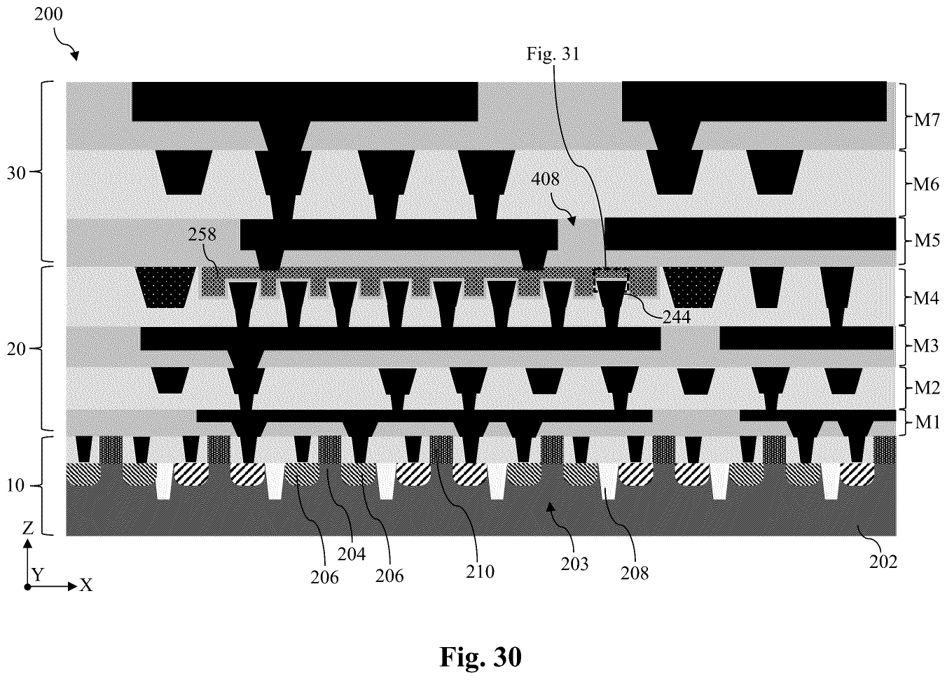

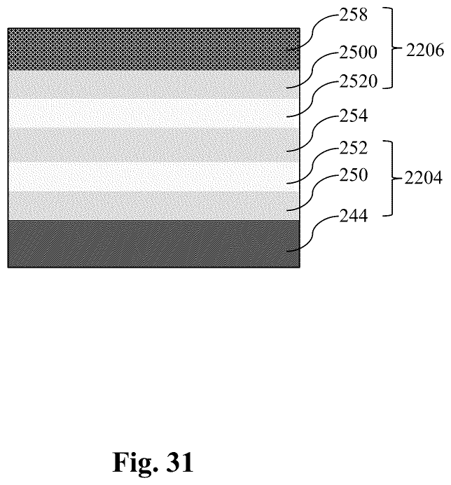

Method 300 may also be used to form double gate back-end device that has not only a back gate structure but also a top gate structure. FIGS. 30 and 31 illustrate a fifth back-end transistor 408 that includes the third back gate structure 2204 below the semiconductor layer 254 and also a top gate structure 2206. The formation of the third back gate structure 2204 and the semiconductor layer 254 has been described above and will be omitted for brevity. Instead of depositing the dielectric layer 256 over the semiconductor layer 254, a top interfacial layer 2520 is deposited over the semiconductor layer 254, a top gate dielectric layer 2500 is deposited over the top interfacial layer 2520, and a top gate electrode layer 258 is deposited over the top gate dielectric layer 2500 to form the top gate structure 2206. Compositions and formation processes for the top interfacial layer 2520, top gate dielectric layer 2500, and the top gate electrode layer 258 may be similar to those of the interfacial layer 252, the gate dielectric layer 250 and the bottom gate electrode layer 244, respectively. For that reason, the detailed description of the top interfacial layer 2520, top gate dielectric layer 2500, and the top gate electrode layer 258 is omitted. While not explicitly shown in FIGS. 30 and 31, the source/drain contacts for the fifth back-end transistor 408 may be elongated along the X direction to have a high drive current configuration.

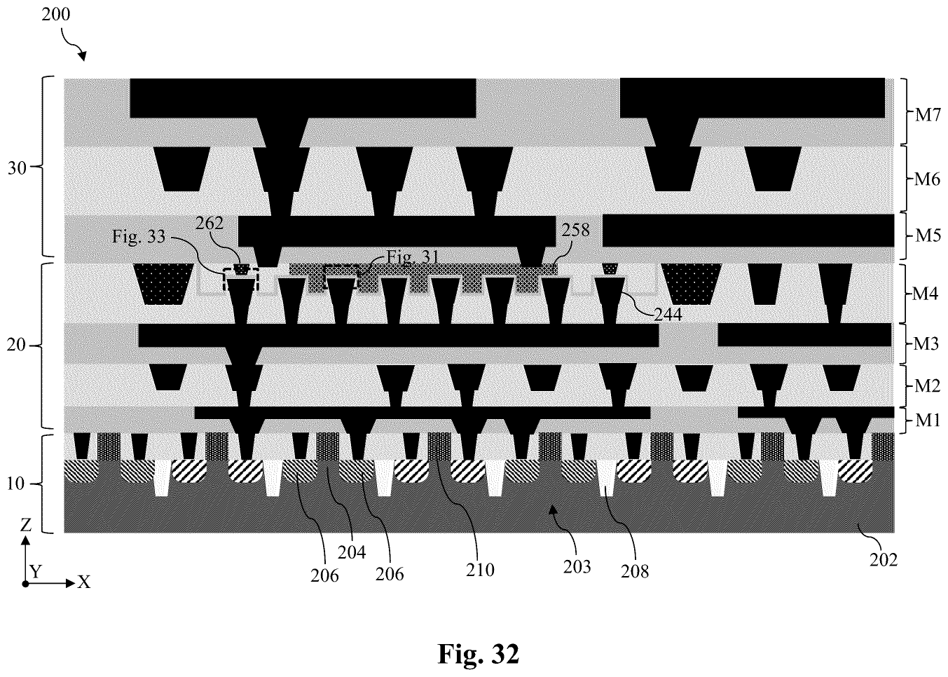

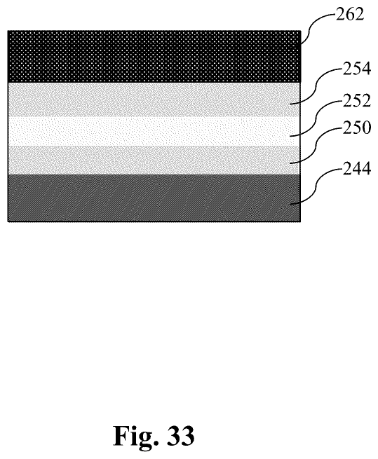

A low leakage configuration of the fifth back-end transistor 408 is illustrated in FIGS. 32 and 33. As illustrated in FIGS. 32 and 33, source/drain contacts 262 are coupled to source/drain regions that are not covered by the top gate structure 2206. The source/drain contacts 262 land directly on the semiconductor layer 254 without extending through the top gate structure 2206. Because the channel length between the two source/drain contacts 262 tracks the ups and downs of the fin-shaped gate structure 244, the channel length is increased to reduce leakage.

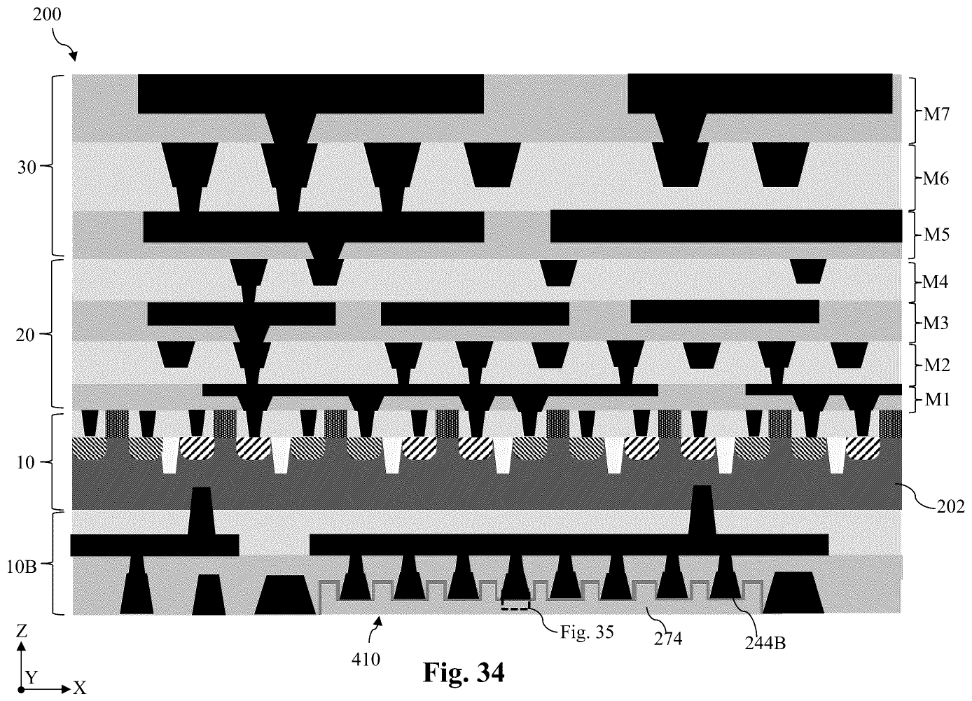

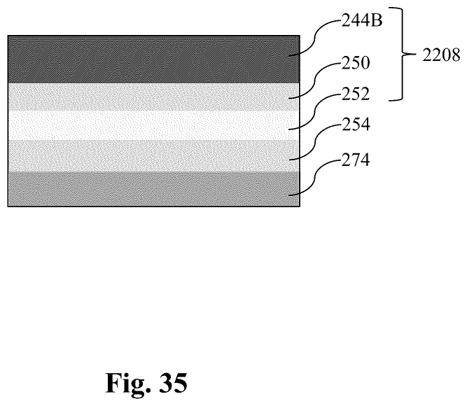

In some embodiments shown in FIGS. 34 and 35, method 300 may also be applied to a backside interconnect structure 10B to form a sixth back-end transistor 410. In FIG. 34, the workpiece 200 includes not only frontside interconnect structures 20 and 30 but also the backside interconnect structure 10B. By following similar operations in method 300 to form backside fin-shaped gate structure 244B and other layers in a backside gate structure 2208, the sixth back-end transistor 410 may be formed in the backside interconnect structure 10B. For better illustration, a portion of the sixth back- end transistor 410 is enlarged and shown in FIG. 35. As shown in FIG. 35, the backside gate structure 2208 includes the backside fin-shaped gate structures 244B, the gate dielectric layer 250, and the interfacial layer 252. The interfacial layer 252 engages a top surface (in the illustration shown in FIG. 35) of the semiconductor layer 254. A backside dielectric layer 274 may be deposited over the semiconductor layer 254 for insulation.

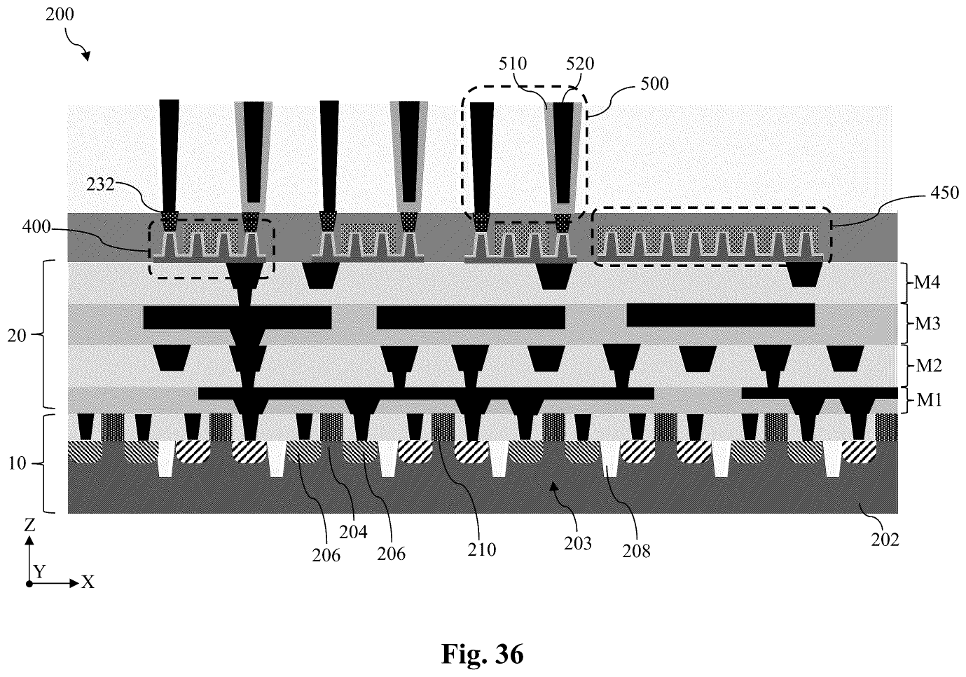

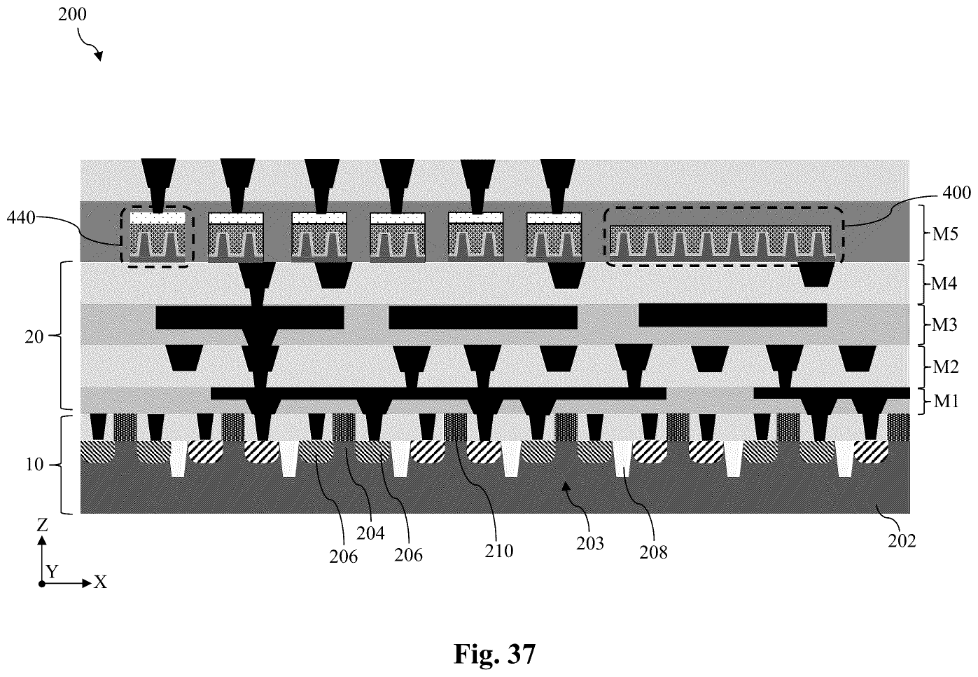

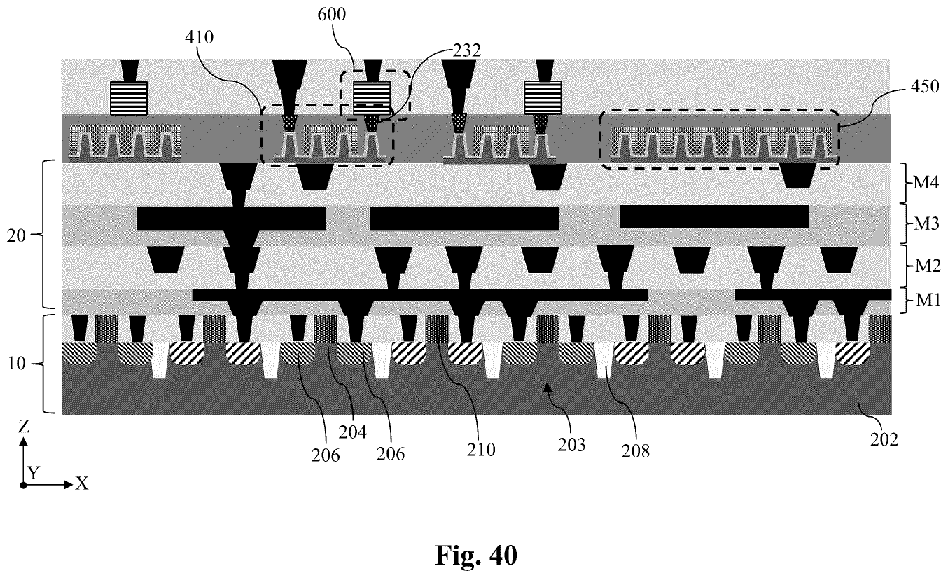

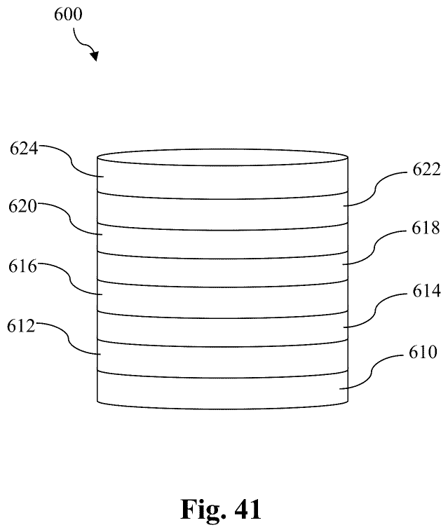

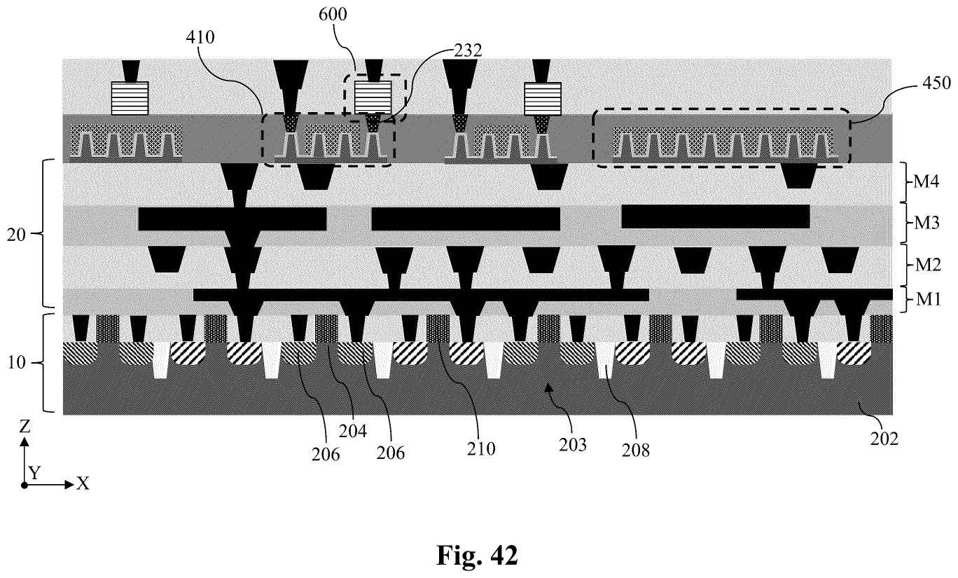

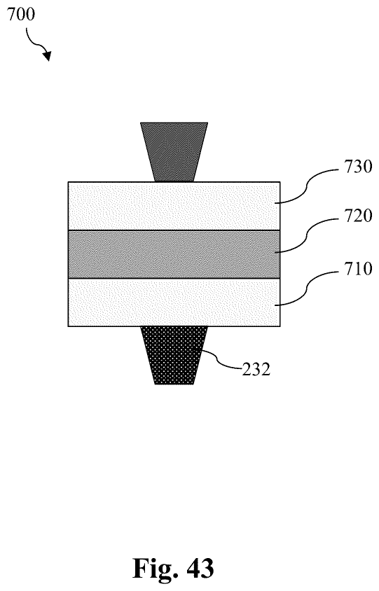

The back-end transistors of the present disclosure, whether in the low-leakage configuration or high drive current configuration, may be implemented in conjunction with different memory devices. FIG. 36 illustrates low leakage first back-end transistor 400 coupled with an embedded dynamic random access memory (eDRAM) device 500. FIGS. 37, 38 and 39 illustrate a high drive current first back-end transistor 400 being integrated into a ferroelectric field effect transistor (FeFET) 440. FIGS. 40 and 41 illustrate a low leakage first back-end transistor 400 being used as an access device for a magnetoresistive random-access memory (MRAM) device 600. FIGS. 42 and 43 illustrates a low leakage first back-end transistor 400 being used as an access device for a resistive random access memory (ReRAM) device 700.

Referring to FIG. 36, the eDRAM device 500 may be disposed on and coupled to a source/drain contact 232 of the first back-end transistor 400. The eDRAM device 500 may have a metal-insulator-metal (MIM) construction. In the depicted embodiment, a trench is formed over the source/drain contact 232 and a high-k dielectric layer 510 is deposited over the trench. In some embodiments, the high-k dielectric layer 510 includes zirconium oxide layer. The eDRAM device 500 also includes a top electrode 520 over the high-k dielectric layer 510. In some instances, the top electrode 520 may include titanium nitride (TiN), tungsten (W) or copper (Cu).

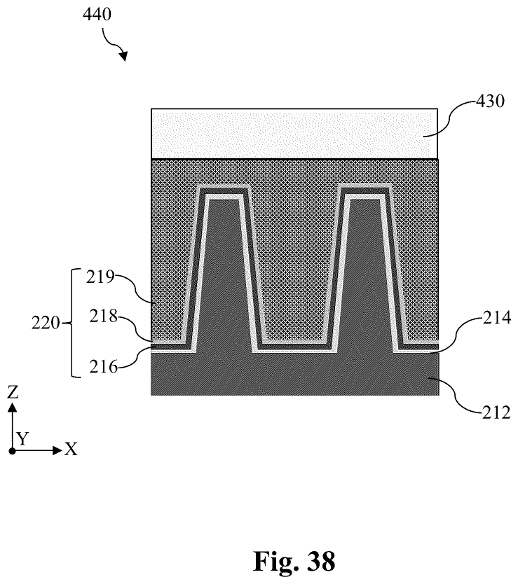

FIG. 37 illustrates FeFETs 440 and a first back-end transistor 400 formed in a fifth metallization layer M5 over the M4 metallization layer. As illustrated in FIG. 38, each of the FeFETs 440 is built upon a first back-end transistor 400 described above. In some embodiments represented in FIG. 38, the FeFET 440 includes a semiconductor layer 214 formed over the fin-shaped structures 212 formed from dielectric spacer materials. An interfacial layer 216 is disposed on and in contact with the semiconductor layer 214. A gate dielectric layer 218 is disposed on and in contact with the interfacial layer 216 and a gate electrode layer 219 is disposed on and in contact with the gate dielectric layer 218. The thicknesses, formation processes, and compositions of the semiconductor layer 214, the interfacial layer 216, the gate dielectric layer 218, and the gate electrode layer 219 have been described in detail above and will not be repeated here for brevity. In the depicted embodiment, while a bottom surface of the gate electrode layer 219 tracks the shape of the fin-shaped structures 212 and has a wavy profile, a top surface of the gate electrode layer 219 is flat or planar. A ferroelectric layer 430 is deposited on and in contact with the flat top surface of the gate electrode layer 219. As a result, an effective width of the interfacial layer 216 is greater than an effective width of the ferroelectric layer 430. The ferroelectric layer 430 may include hafnium zirconium oxide (HZO) and has a crystalline structure that exhibits ferroelectricity. In some embodiments not explicitly illustrated in the figures, the gate dielectric layer 218 may be completely omitted from the structure shown in FIG. 38.

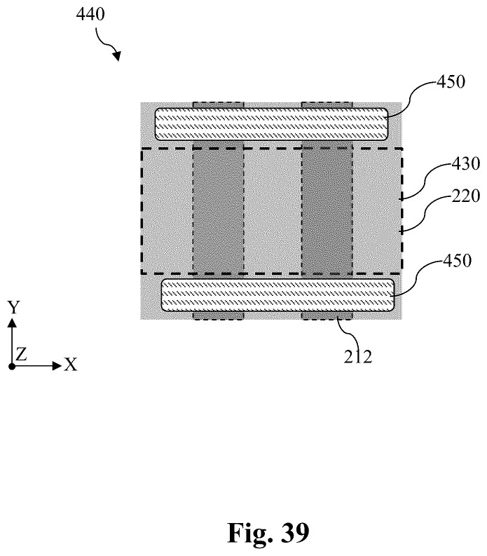

Source/drain regions and source/drain contacts of the FeFET 440 are not shown in FIG. 38 because the FeFET in FIG. 38 has a high drive current configuration. As shown in FIG. 39, in a top view where the Y direction goes upward on the paper rather than going into the paper, a channel width of the FeFET 440 extends along the X direction, perpendicular to the Y direction, along width the fin-shaped structures 212 extends lengthwise and in parallel. As shown in FIG. 39, the source/drain contacts 450 of the FeFET 440 are spaced apart on both sides of the ferroelectric layer 430 or the gate structure 220. A gate voltage applied to the FeFET 440 may change a dipole moment in the ferroelectric layer 430. The dipole moment may act as a bias to change the threshold voltage of the FeFET 440. In that sense, the FeFET 440 may function as a memory device.

Referring to FIG. 40, the MRAM device 600 may be disposed on and coupled to a source/drain contact 232 of the first back-end transistor 400. The MRAM device 600 may have magnetic tunnel junction (MTJ) construction. In the embodiment depicted in FIG. 41, the MRAM device 600 include a bottom electrode 610, a synthetic anti-ferromagnetic (SAF) layer 612 over the bottom electrode 610, a spacer layer 614 over the SAF layer 612, a reference layer 616 over the spacer layer 614, an oxide barrier layer 618 over the reference layer 616, a free layer 620 over the oxide barrier layer 618, a capping layer 622 over the free layer 620, and a top electrode 624 over the capping layer 622. In some embodiments, the bottom electrode 610 and the top electrode 624 may include titanium nitride (TiN), copper (Cu), tungsten (W), or nickel (Ni). The SAF layer 612 may include cobalt (Co), platinum (Pt), or a combination thereof. The spacer layer 614 and the capping layer 622 may include titanium (Ti) or tantalum (Ta). The free layer 620 and the reference layer 616 may include cobalt (Co), iron (Fc), boron (B), ruthenium (Ru), or the like. The oxide barrier layer 618 may include magnesium oxide (MgO), aluminum oxide (Al₂O₃), or the like.

Referring to FIG. 42, the ReRAM device 700 may be disposed on and coupled to a source/drain contact 232 of the first back-end transistor 400. As shown in FIG. 43, ReRAM device 700 may include a bottom electrode 710, a switching medium (SM) layer 720 over the bottom electrode 710, and top electrode 730 over the SM layer 720. In some embodiments, the bottom electrode 710 and the top electrode 730 may include titanium nitride (TiN), tantalum nitride (TaN), tungsten (W), or ruthenium (Ru). The SM layer 720 may include hafnium oxide.

In one exemplary aspect, the present disclosure is directed to a semiconductor structure. The semiconductor structure includes a semiconductor substrate, a plurality of transistors disposed on the semiconductor substrate and including a plurality of gate structures extending lengthwise along a first direction, a metallization layer disposed over the plurality of transistors, the metallization layer including a plurality of metal layers and a plurality of contact vias, a dielectric layer over the metallization layer, a plurality of dielectric fins extending parallel along the first direction and disposed over the dielectric layer, a semiconductor layer disposed conformally over the plurality of dielectric fins, a source contact and a drain contact disposed directly on the semiconductor layer, and a gate structure disposed over the semiconductor layer and between the source contact and the drain contact.

In some embodiments, the semiconductor layer includes a low-dimensional semiconductor material. In some embodiments, the low-dimensional semiconductor material includes molybdenum sulfide (MoS₂), tungsten selenide (WSe₂), carbon nanotubes, indium oxide, or indium gallium zinc oxide (IGZO). In some embodiments, the gate structure is disposed between the source contact and the drain contact along the first direction. In some instances, the gate structure is disposed between the source contact and the drain contact along a second direction perpendicular to the first direction. In some implementations, the gate structure includes an interfacial layer disposed on the semiconductor layer, a gate dielectric layer over the interfacial layer, and a gate electrode over the gate dielectric layer. In some embodiments, the interfacial layer includes silicon oxide, van der Waals air gap, aluminum oxide, or titanium oxide. In some instances, the gate dielectric layer includes hafnium oxide, zirconium oxide, hafnium zirconium oxide, or a combination thereof. In some embodiments, the gate electrode includes titanium nitride, tantalum nitride, tungsten, ruthenium, or copper.

In another exemplary aspect, the present disclosure is directed to a semiconductor structure. The semiconductor structure includes a first dielectric layer, a plurality of metal lines partially disposed in the first dielectric layer and extending lengthwise along a first direction, a gate dielectric layer conformally disposed over and in direct contact with the first dielectric layer and top surfaces of the plurality of metal lines, an interfacial layer conformally disposed over the gate dielectric layer, a semiconductor layer disposed over the interfacial layer, a second dielectric layer disposed over the semiconductor layer, and a source contact and a drain contact extending through the second dielectric layer to contact the semiconductor layer.

In some embodiments, a topmost surface of the first dielectric layer is higher than the top surfaces of the plurality of metal lines. In some embodiments, the topmost surface of the first dielectric layer is coplanar with a top surface of the second dielectric layer. In some implementations, a portion of the gate dielectric layer, a portion of the interfacial layer, and a portion of the semiconductor layer extend below the top surfaces of the plurality of metal lines. In some embodiments, the gate dielectric layer includes hafnium oxide, zirconium oxide, hafnium zirconium oxide, or a combination thereof. In some embodiments, the semiconductor layer includes molybdenum sulfide (MoS₂), tungsten selenide (WSe₂), cuprous oxide (Cu₂O), carbon nanotubes, indium oxide, or indium gallium zinc oxide (IGZO).

In yet another exemplary aspect, the present disclosure is directed to a method. The method includes forming transistors on a substrate, forming a metallization layer over the transistors such that the metallization layer includes a first dielectric layer, and a plurality of metal lines disposed in the first dielectric layer and extending lengthwise along a first direction, etching the first dielectric layer and the plurality of metal lines to form a recess, depositing a gate dielectric layer over the recess, depositing an interfacial layer over the gate dielectric layer, depositing a semiconductor layer over the interfacial layer, depositing a second dielectric layer over the semiconductor layer, after the depositing of the second dielectric layer, planarizing the first dielectric layer and the second dielectric layer, and forming a source contact and a drain contact through the second dielectric layer to contact the semiconductor layer.

In some embodiments, after the etching, top surfaces of the plurality of metal lines in the recess rise above a top surface of the first dielectric layer in the recess. In some implementations, the gate dielectric layer is in direct contact with the top surfaces of the plurality of metal lines. In some instances, the semiconductor layer includes molybdenum sulfide (MoS₂), tungsten selenide (WSe₂), cuprous oxide (Cu₂O), carbon nanotubes, indium oxide, or indium gallium zinc oxide (IGZO). In some embodiments, the gate dielectric layer includes hafnium oxide, zirconium oxide, hafnium zirconium oxide, or a combination thereof.

The foregoing outlines features of several embodiments so that those of ordinary skill in the art may better understand the aspects of the present disclosure. Those of ordinary skill in the art should appreciate that they may readily use the present disclosure as a basis for designing or modifying other processes and structures for carrying out the same purposes and/or achieving the same advantages of the embodiments introduced herein. Those of ordinary skill in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
a semiconductor substrate;
a plurality of transistors disposed on the semiconductor substrate and comprising a plurality of gate structures extending lengthwise along a first direction;
a metallization layer disposed over the plurality of transistors, the metallization layer comprising a plurality of metal layers and a plurality of contact vias;
a dielectric layer over the metallization layer;
a plurality of dielectric fins extending parallel along the first direction and disposed over the dielectric layer;
a semiconductor layer disposed conformally over the plurality of dielectric fins;
a source contact and a drain contact disposed directly on the semiconductor layer; and
a gate structure disposed over the semiconductor layer and between the source contact and the drain contact.

2. The semiconductor structure of claim 1, wherein the semiconductor layer comprises a low-dimensional semiconductor material.

3. The semiconductor structure of claim 2, wherein the low-dimensional semiconductor material comprises molybdenum sulfide (MoS₂), tungsten selenide (WSe₂), carbon nanotubes, indium oxide, or indium gallium zinc oxide (IGZO).

4. The semiconductor structure of claim 1, wherein the gate structure is disposed between the source contact and the drain contact along the first direction.

5. The semiconductor structure of claim 1, wherein the gate structure is disposed between the source contact and the drain contact along a second direction perpendicular to the first direction.

6. The semiconductor structure of claim 1, wherein the gate structure comprises:
an interfacial layer disposed on the semiconductor layer;
a gate dielectric layer over the interfacial layer; and
a gate electrode over the gate dielectric layer.

7. The semiconductor structure of claim 6, wherein the interfacial layer comprises silicon oxide, van der Waals air gap, aluminum oxide, or titanium oxide.

8. The semiconductor structure of claim 6, wherein the gate dielectric layer comprises hafnium oxide, zirconium oxide, hafnium zirconium oxide, or a combination thereof.

9. The semiconductor structure of claim 6, wherein the gate electrode comprises titanium nitride, tantalum nitride, tungsten, ruthenium, or copper.

10. A semiconductor structure, comprising:
a first dielectric layer;
a plurality of metal lines partially disposed in the first dielectric layer and extending lengthwise along a first direction;
a gate dielectric layer conformally disposed over and in direct contact with the first dielectric layer and top surfaces of the plurality of metal lines;
an interfacial layer conformally disposed over the gate dielectric layer;
a semiconductor layer disposed over the interfacial layer;
a second dielectric layer disposed over the semiconductor layer; and
a source contact and a drain contact extending through the second dielectric layer to contact the semiconductor layer.

11. The semiconductor structure of claim 10, wherein a topmost surface of the first dielectric layer is higher than the top surfaces of the plurality of metal lines.

12. The semiconductor structure of claim 11, wherein the topmost surface of the first dielectric layer is coplanar with a top surface of the second dielectric layer.

13. The semiconductor structure of claim 10, wherein a portion of the gate dielectric layer, a portion of the interfacial layer, and a portion of the semiconductor layer extend below the top surfaces of the plurality of metal lines.

14. The semiconductor structure of claim 10, wherein the gate dielectric layer comprises hafnium oxide, zirconium oxide, hafnium zirconium oxide, or a combination thereof.

15. The semiconductor structure of claim 10, wherein the semiconductor layer comprises molybdenum sulfide (MoS₂), tungsten selenide (WSe₂), cuprous oxide (Cu₂O), carbon nanotubes, indium oxide, or indium gallium zinc oxide (IGZO).

16. A method, comprising:
forming transistors on a substrate;
forming a metallization layer over the transistors, the metallization layer comprising:
a first dielectric layer, and
a plurality of metal lines disposed in the first dielectric layer and extending lengthwise along a first direction;
etching the first dielectric layer and the plurality of metal lines to form a recess;
depositing a gate dielectric layer over the recess;
depositing an interfacial layer over the gate dielectric layer;
depositing a semiconductor layer over the interfacial layer;
depositing a second dielectric layer over the semiconductor layer;
after the depositing of the second dielectric layer, planarizing the first dielectric layer and the second dielectric layer; and
forming a source contact and a drain contact through the second dielectric layer to contact the semiconductor layer.

17. The method of claim 16, wherein, after the etching, top surfaces of the plurality of metal lines in the recess rise above a top surface of the first dielectric layer in the recess.

18. The method of claim 17, wherein the gate dielectric layer is in direct contact with the top surfaces of the plurality of metal lines.

19. The method of claim 16, wherein the semiconductor layer comprises molybdenum sulfide (MoS₂), tungsten selenide (WSe₂), cuprous oxide (Cu₂O), carbon nanotubes, indium oxide, or indium gallium zinc oxide (IGZO).

20. The method of claim 16, wherein the gate dielectric layer comprises hafnium oxide, zirconium oxide, hafnium zirconium oxide, or a combination thereof.
